(19) United States
(12) Patent Application Publication
(10) Pub. No.: US 2023/0323530 A1
(43) Pub. Date: Oct. 12, 2023

(54) NIOBIUM, VANADIUM, TANTALUM FILM FORMING COMPOSITIONS AND DEPOSITION OF GROUP V (FIVE) CONTAINING FILMS USING THE SAME

(71) Applicants: L'Air Liquide, Société Anonyme pour l'Etude et l'Exploitatation des Procédés Georges Claude, Paris (FR); American Air Liquide, Inc., Fremont, CA (US)

(72) Inventors: Daehyeon KIM, Hwaseong (KR); Wontae NOH, Seoul (KR); Jooho LEE, Seoul (KR); Venkateswara R. PALLEM, Hockessin, DE (US)

(21) Appl. No.: 17/718,598

(22) Filed: Apr. 12, 2022

(51) Int. Cl. C23C 16/30; C23C 16/40; C23C 16/455; H01M 4/525; H01M 4/505; H01M 4/36; H01M 4/58

(52) U.S. Cl. CPC C23C 16/303; C23C 16/405; C23C 16/45527; H01M 4/58; H01M 4/505; H01M 4/366; H01M 4/525

(57) ABSTRACT

Methods for forming a Group V-containing film comprise:
a) exposing a substrate to a vapor of a Group V (five)-containing film forming composition;
b) exposing the substrate to a co-reactant; and
c) repeating the steps of a) and b) until a desired thickness of the Group V (five)-containing film is deposited on the substrate using a vapor deposition process,

wherein the Group V (five)-containing film forming composition comprises a precursor having the formula:

wherein M is Group V (five) element, vanadium (V), niobium (Nb), or tantalum (Ta); R¹ to R⁸ each is H, a C₁-C₆ alkyl group, a fluoro group, an alkylsilyl group, a germyl group, an alkylamide or an alkylsilylamide; m=1 to 5, n=1 to 5.

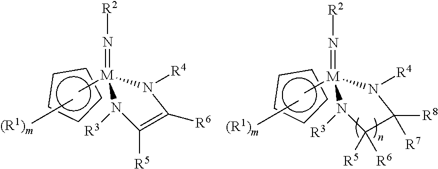

### TECHNICAL FIELD

The present invention relates to Group V (five)-containing film forming compositions, methods of synthesizing the same, and methods of using the same to deposit Group V-containing films on substrates via vapor deposition processes. The Group V-containing film forming composition comprises a precursor having the formula:

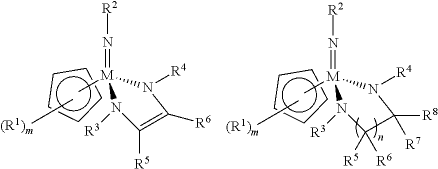

wherein M is Group V (five) element, vanadium (V), niobium (Nb), or tantalum (Ta);
R¹ to R⁸ each is H, a C₁-C₆ alkyl group, a fluoro group, an alkylsilyl group, a germyl group, an alkylamide or an alkylsilylamide; m=1 to 5, n=1 to 5.

### BACKGROUND

Today, the needs for metal organic precursors in liquid state at room temperature or close to room temperature, whcih have high volatility, thermal stability and high versatility, and suitable for various applications in the semiconductor manufacture, still exist. Interest for conductive (resistivity 1000 μΩ·cm), Group V (five) (V, Nb, Ta) metal containing thin films deposited by atomic layer deposition (ALD) has risen in the past few years for several main applications such as: copper diffusion barrier in back end of line (BELL) applications, complementary metal-oxide-semiconductor (CMOS) metal gate, electrodes for Metal-Insulator-Metal applications (DRAM, etc.), and the thin film transistor liquid crystal display (TFT-LCD) applications. Group V (five) (V, Nb, Ta) metal containing films are also of particular interest for high-k layers in memory devices.

Halides, such as CpNbCl₄ (CAS 33114-1507), NbF₅, NbBr₅ (Thin solid films, 1981, 79, 75), NbCl₅ (Crystal growth, 1978, 45, 37) and TaCl₅ (U.S. Pat. No. 6,268,288), have been widely investigated. However, some by-products generated during the deposition process, such as HCl or Cl₂, cause surface/interface roughness that can be detrimental to the final films. Moreover, Cl or F impurities are detrimental to the final electrical properties. It is therefore expected to find new compounds having sufficient volatility but without containing Cl, F, or Br atoms.

Many Group V (five) precursors have been considered to enable such deposition. Examples include; Alkoxides such as penta-ethoxy-tantalum (PET) are widely used and disclosed However; they lead to oxygen containing films and are not suitable for the deposition of metal containing films which are used in particular as electrodes and which should not contain oxygen even at trace levels. The same problem is observed for compounds such as Cp₂Nb(H)(CO), CpNb(CO)₄ (J. Organomet. Chem., 557 (1998) 77-92), V(CO)₆ (Thermochimica Acta, 1984, 75, 71), (η⁵-C₅H₅)V(CO)₄ (M. L. Green, R. A. Levy, J. Metals 37 (1985) 63).

U.S. Pat. No. 6,379,748 discloses an improvement to Ta(OEt)₅ (PET). Alkyl bonds have been introduced, e.g. by using TaMe₃(OEt)₂ instead of Ta(OEt)₅ (PET). Volatility was thereby significantly improved without affecting the melting point. However, TaMe₃(OEt)₂ does not allow versatile deposition: in particular, oxygen free metal cannot be obtained.

U.S. Pat. No. 6,368,398 discloses another improvement with the use for instance of Ta[OC(O)C(CH₃)₃]₅, however with the same limitation as disclosed here above.

WO 2002/20870 discloses the deposition of Ta₂O₅ use using tert-butylimido(tris(diethylamido)tantalum (TBTDET).

U.S. Pat. No. 6,593,484 and US 2004/0219784 disclose a method of deposition of tantalum nitride films by sequential injection of TBTDET or tertiary amyl imido-tris-dimethylamido tantalum (Ta(NC(CH₃)₂C₂H₅)(N(CH₃)₂)₃ (TAIMATA) and other N source.

U.S. Pat. No. 6,379,748 discloses Ta(Me₃SiCp)₂H₃, which is a biscyclopentadienyl Ta hydride and is a solid having a low volatility.

U.S. Pat. No. 8,460,989 discloses a method of deposition of Niobium-containing films by CVD and ALD of NbCp(=NtBu)(NEtMe)₂.

### SUMMARY

Disclosed is a method for forming a Group V (five)-containing film, the method comprising the steps of:
a) exposing a substrate to a vapor of a Group V (five)-containing film forming composition;
b) exposing the substrate to a co-reactant; and
c) repeating the steps of a) and b) until a desired thickness of the Group V (five)-containing film is deposited on the substrate using a vapor deposition process,
wherein the Group V (five)-containing film forming composition comprises a precursor having the formula:

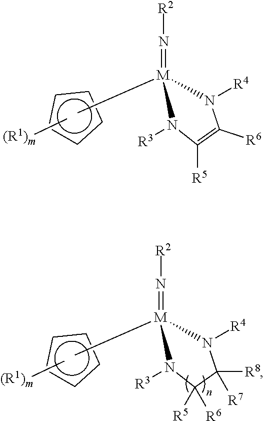

wherein M is Group V (five) element, vanadium (V), niobium (Nb), or tantalum (Ta);
R¹ to R⁸ each is H, a C₁-C₆ alkyl group, a fluoro group, an alkylsilyl group, a germyl group, an alkylamide or an alkylsilylamide; m=1 to 5, n=1 to 5. The disclosed methods may include one or more of the following aspects:
further comprising the steps of
introducing an inert gas purge following the steps a) and b), respectively, to separate each exposure;
the inert gas purge using an inert gas selected from N₂, He, Ar, Kr, or Xe;
the inert gas purge using Ar;
further comprising the step of plasma treating the co-reactant;
the co-reactant being selected from the group consisting of O₂, O₃, H₂O, H₂O₂, NO, N₂O, NO₂, oxygen radicals thereof, and mixtures thereof;
the co-reactant being O₃;
the co-reactant being selected from the group consisting of H₂, H₂CO, N₂H₄, NH₃, an amine, a hydrazine N(SiH₃)₃, B₂H₆, Si₂H₆ radicals thereof, and mixtures thereof;
the co-reactant being NH₃ or O₃;
the precursor being Niobium tButyl Imido Cyclopentadienyl tAmyl-Diazadienyl, CpNb(=NtBu)(tAm₂-DAD);
the precursor being (R³⁻⁷Cp)Nb(=NR¹)(R²₂-DAD),

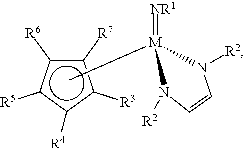

wherein DAD=Diazadiene; R¹ is tBu or nPr; R² is Me, Et, nPr, iPr, nBu, tBu, nPentyl or tAm;
R³, R⁴, R⁵, R⁶ and R⁷ each is Independently H, Me, Et, nPr, iPr, nBu, tBu or sBu;
(R³⁻⁷Cp)Nb(=NR¹)(R²₂-DAD) including (Cp)Nb(=NtBu)(Me₂-DAD), (Cp)Nb(=NtBu)(Et₂-DAD), (Cp)Nb(=NtBu)(nPr₂-DAD), (Cp)Nb(=NtBu)(iPr₂-DAD), (Cp)Nb(=NtBu)(nBu₂-DAD), (Cp)Nb(=NtBu)(tBu₂-DAD), (Cp)Nb(=NtBu)(nPentyl₂-DAD), (Cp)Nb(=NtBu)(tAm₂-DAD), (MeCp)Nb(=NtBu)(Me₂-DAD), (MeCp)Nb(=NtBu)(Et₂-DAD), (MeCp)Nb(=NtBu)(nPr₂-DAD), (MeCp)Nb(=NtBu)(iPr₂-DAD), (MeCp)Nb(=NtBu)(nBu₂-DAD), (MeCp)Nb(=NtBu)(tBu₂-DAD), (MeCp)Nb(=NtBu)(nPentyl₂-DAD), (MeCp)Nb(=NtBu)(tAm₂-DAD), (EtCp)Nb(=NtBu)(Me₂-DAD), (EtCp)Nb(=NtBu)(Et₂-DAD), (EtCp)Nb(=NtBu)(nPr₂-DAD), (EtCp)Nb(=NtBu)(iPr₂-DAD), (EtCp)Nb(=NtBu)(nBu₂-DAD), (EtCp)Nb(=NtBu)(tBu₂-DAD), (EtCp)Nb(=NtBu)(nPentyl₂-DAD), (EtCp)Nb(=NtBu)(tAm₂-DAD), (nPrCp)Nb(=NtBu)(Me₂-DAD), (nPrCp)Nb(=NtBu)(Et₂-DAD), (nPrCp)Nb(=NtBu)(nPr₂-DAD), (nPrCp)Nb(=NtBu)(iPr₂-DAD), (nPrCp)Nb(=NtBu)(nBu₂-DAD), (nPrCp)Nb(=NtBu)(tBu₂-DAD), (nPrCp)Nb(=NtBu)(nPentyl₂-DAD), (nPrCp)Nb(=NtBu)(tAm₂-DAD), (iPrCp)Nb(=NtBu)(Me₂-DAD), (iPrCp)Nb(=NtBu)(Et₂-DAD), (iPrCp)Nb(=NtBu)(nPr₂-DAD), (iPrCp)Nb(=NtBu)(iPr₂-DAD), (iPrCp)Nb(=NtBu)(nBu₂-DAD), (iPrCp)Nb(=NtBu)(tBu₂-DAD), (iPrCp)Nb(=NtBu)(nPentyl₂-DAD), (iPrCp)Nb(=NtBu)(tAm₂-DAD), (nBuCp)Nb(=NtBu)(Me₂-DAD), (nBuCp)Nb(=NtBu)(Et₂-DAD), (nBuCp)Nb(=NtBu)(nPr₂-DAD), (nBuCp)Nb(=NtBu)(iPr₂-DAD), (nBuCp)Nb(=NtBu)(nBu₂-DAD), (nBuCp)Nb(=NtBu)(tBu₂-DAD), (nBuCp)Nb(=NtBu)(nPentyl₂-DAD), (nBuCp)Nb(=NtBu)(tAm₂-DAD), (tBuCp)Nb(=NtBu)(Me₂-DAD), (tBuCp)Nb(=NtBu)(Et₂-DAD), (tBuCp)Nb(=NtBu)(nPr₂-DAD), (tBuCp)Nb(=NtBu)(iPr₂-DAD), (tBuCp)Nb(=NtBu)(nBu₂-DAD), (tBuCp)Nb(=NtBu)(tBu₂-DAD), (tBuCp)Nb(=NtBu)(nPentyl₂-DAD), (tBuCp)Nb(=NtBu)(tAm₂-DAD), (sBuCp)Nb(=NtBu)(Me₂-DAD), (sBuCp)Nb(=NtBu)(Et₂-DAD), (sBuCp)Nb(=NtBu)(nPr₂-DAD), (sBuCp)Nb(=NtBu)(iPr₂-DAD), (sBuCp)Nb(=NtBu)(nBu₂-DAD), (sBuCp)Nb(=NtBu)(tBu₂-DAD), (sBuCp)Nb(=NtBu)(nPentyl₂-DAD), (sBuCp)Nb(=NtBu)(tAm₂-DAD), (Di-MeCp)Nb(=NtBu)(Me₂-DAD), (Di-MeCp)Nb(=NtBu)(Et₂-DAD), (Di-MeCp)Nb(=NtBu)(nPr₂-DAD), (Di-MeCp)Nb(=NtBu)(iPr₂-DAD), (Di-MeCp)Nb(=NtBu)(nBu₂-DAD), (Di-MeCp)Nb(=NtBu)(tBu₂-DAD), (Di-MeCp)Nb(=NtBu)(nPentyl₂-DAD), (Di-MeCp)Nb(=NtBu)(tAm₂-DAD), (MeEtCp)Nb(=NtBu)(Me₂-DAD), (MeEtCp)Nb(=NtBu)(Et₂-DAD), (MeEtCp)Nb(=NtBu)(nPr₂-DAD), (MeEtCp)Nb(=NtBu)(iPr₂-DAD), (MeEtCp)Nb(=NtBu)(nBu₂-DAD), (MeEtCp)Nb(=NtBu)(tBu₂-DAD), (MeEtCp)Nb(=NtBu)(nPentyl₂-DAD), (MeEtCp)Nb(=NtBu)(tAm₂-DAD), (MePrCp)Nb(=NtBu)(Me₂-DAD), (MePrCp)Nb(=NtBu)(Et₂-DAD). (MePrCp)Nb(=NtBu)(nPr₂-DAD), (MePrCp)Nb(=NtBu)(iPr₂-DAD), (MePrCp)Nb(=NtBu)(nBu₂-DAD), (MePrCp)Nb(=NtBu)(tBu₂-DAD), (MePrCp)Nb(=NtBu)(nPentyl₂-DAD), (MePrCp)Nb(=NtBu)(tAm₂-DAD), (Penta-MeCp)Nb(=NtBu)(Me₂-DAD), (Penta-MeCp)Nb(=NtBu)(Et₂-DAD), (Penta-MeCp)Nb(=NtBu)(nPr₂-DAD), (Penta-MeCp)Nb(=NtBu)(iPr₂-DAD), (Penta-MeCp)Nb(=NtBu)(nBu₂-DAD), (Penta-MeCp)Nb(=NtBu)(tBu₂-DAD), (Penta-MeCp)Nb(=NtBu)(nPentyl₂-DAD), (Penta-MeCp)Nb(=NtBu)(tAm₂-DAD), (Cp)Nb(=NnPr)(Me₂-DAD), (Cp)Nb(=NnPr)(Et₂-DAD), (Cp)Nb(=NnPr)(nPr₂-DAD), (Cp)Nb(=NnPr)(iPr₂-DAD), (Cp)Nb(=NnPr)(nBu₂-DAD), (Cp)Nb(=NnPr)(tBu₂-DAD), (Cp)Nb(=NnPr)(nPentyl₂-DAD), (Cp)Nb(=NnPr)(tAm₂-DAD), (MeCp)Nb(=NnPr)(Me₂-DAD), (MeCp)Nb(=NnPr)(Et₂-DAD), (MeCp)Nb(=NnPr)(nPr₂-DAD), (MeCp)Nb(=NnPr)(iPr₂-DAD), (MeCp)Nb(=NnPr)(nBu₂-DAD), (MeCp)Nb(=NnPr)(tBu₂-DAD), (MeCp)Nb(=NnPr)(nPentyl₂-DAD), (MeCp)Nb(=NnPr)(tAm₂-DAD), (EtCp)Nb(=NnPr)(Me₂-DAD), (EtCp)Nb(=NnPr)(Et₂-DAD), (EtCp)Nb(=NnPr)(nPr₂-DAD), (EtCp)Nb(=NnPr)(iPr₂-DAD), (EtCp)Nb(=NnPr)(nBu₂-DAD), (EtCp)Nb(=NnPr)(tBu₂-DAD), (EtCp)Nb(=NnPr)(nPentyl₂-DAD), (EtCp)Nb(=NnPr)(tAm₂-DAD), (nPrCp)Nb(=NnPr)(Me₂-DAD), (nPrCp)Nb(=NnPr)(Et₂-DAD), (nPrCp)Nb(=NnPr)(nPr₂-DAD), (nPrCp)Nb(=NnPr)(iPr₂-DAD), (nPrCp)Nb(=NnPr)(nBu₂-DAD), (nPrCp)Nb(=NnPr)(tBu₂-DAD), (nPrCp)Nb(=NnPr)(nPentyl₂-DAD), (nPrCp)Nb(=NnPr)(tAm₂-DAD), (iPrCp)Nb(=NnPr)(Me₂-DAD), (iPrCp)Nb(=NnPr)(Et₂-DAD), (iPrCp)Nb(=NnPr)(nPr₂-DAD), (iPrCp)Nb(=NnPr)(iPr₂-DAD), (iPrCp)Nb(=NnPr)(nBu₂-DAD), (iPrCp)Nb(=NnPr)(tBu₂-DAD), (iPrCp)Nb(=NnPr)(nPentyl₂-DAD), (iPrCp)Nb(=NnPr)(tAm₂-DAD), (nBuCp)Nb(=NnPr)(Me₂-DAD), (nBuCp)Nb(=NnPr)(Et₂-DAD), (nBuCp)Nb(=NnPr)(nPr₂-DAD), (nBuCp)Nb(=NnPr)(iPr₂-DAD), (nBuCp)Nb(=NnPr)(nBu₂-DAD), (nBuCp)Nb(=NnPr)(tBu₂-DAD), (nBuCp)Nb(=NnPr)(nPentyl₂-DAD), (nBuCp)Nb(=NnPr)(tAm₂-DAD), (tBuCp)Nb(=NnPr)(Me₂-DAD), (tBuCp)Nb(=NnPr)(Et₂-DAD), (tBuCp)Nb(=NnPr)(nPr₂-DAD), (tBuCp)Nb(=NnPr)(iPr₂-DAD), (tBuCp)Nb(=NnPr)(nBu₂-DAD), (tBuCp)Nb(=NnPr)(tBu₂-DAD), (tBuCp)Nb(=NnPr)(nPentyl₂-DAD), (tBuCp)Nb(=NnPr)(tAm₂-DAD), (sBuCp)Nb(=NnPr)(Me₂-DAD), (sBuCp)Nb(=NnPr)(Et₂-DAD), (sBuCp)Nb(=NnPr)(nPr₂-DAD), (sBuCp)Nb(=NnPr)(iPr₂-DAD), (sBuCp)Nb(=NnPr)(nBu₂-DAD), (sBuCp)Nb(=NnPr)(tBu₂-DAD), (sBuCp)Nb(=NnPr)(nPentyl₂-DAD), (sBuCp)Nb(=NnPr)(tAm₂-DAD), (Di-MeCp)Nb(=NnPr)(Me₂-DAD), (Di-MeCp)Nb(=NnPr)(Et₂-DAD), (Di-MeCp)Nb(=NnPr)(nPr₂-DAD), (Di-MeCp)Nb(=NnPr)(iPr₂-DAD), (Di-MeCp)Nb(=NnPr)(nBu₂-DAD), (Di-MeCp)Nb(=NnPr)(tBu₂-DAD) (Di-MeCp)Nb(=NnPr)(nPentyl₂-DAD), (Di-MeCp)Nb(=NnPr)(tm₂-DAD), (MeEtCp)Nb(=NnPr)(Me₂-DAD), (MeEtCp)Nb(=NnPr)(Et₂-DAD), (MeEtCp)Nb(=NnPr)(nPr₂-DAD), (MeEtCp)Nb(=NnPr)(iPr₂-DAD), (MeEtCp)Nb(=NnPr)(nBu₂-DAD), (MeEtCp)Nb(=NnPr)(tBu₂-DAD), (MeEtCp)Nb(=NnPr)(nPentyl₂-DAD), (MeEtCp)Nb(=NnPr)(tAm₂-DAD), (MePrCp)Nb(=NnPr)(Me₂-DAD), (MePrCp)Nb(=NnPr)(Et₂-DAD), (MePrCp)Nb(=NnPr)(nPr₂-DAD), (MePrCp)Nb(=NnPr)(iPr₂-DAD), (MePrCp)Nb(=NnPr)(nBu₂-DAD), (MePrCp)Nb(=NnPr)(tBu₂-DAD), (MePrCp)Nb(=NnPr)(nPentyl₂-DAD), (MePrCp)Nb(=NnPr)(tAm₂-DAD), (Penta-MeCp)Nb(=NnPr)(Me₂-DAD), (Penta-MeCp)Nb(=NnPr)(Et₂-DAD), (Penta-MeCp)Nb(=NnPr)(nPr₂-DAD), (Penta-MeCp)Nb(=NnPr)(iPr₂-DAD), (Penta-MeCp)Nb(=NnPr)(nBu₂-DAD), (Penta-MeCp)Nb(=NnPr)(tBu₂-DAD), (Penta-MeCp)Nb(=NnPr)(nPentyl₂-DAD), or (Penta-MeCp)Nb(=NnPr)(tAm₂-DAD).
The precursor being (R³⁻⁷Cp)Nb(=NR¹)(R²₂-EDA),

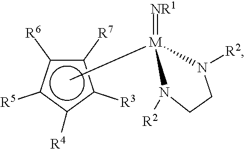

wherein EDA is Ethylenediamine; R¹ is tBu or nPr; R² is Me, Et, nPr, iPr, nBu, tBu, nPentyl or tAm; R³, R⁴, R⁵, R⁶ and R⁷ each is Independently H, Me, Et, nPr, iPr, nBu, tBu or sBu;
(R³⁻⁷Cp)Nb(=NR¹)(R²₂-EDA) including (Cp)Nb(=NtBu)(EDA), (Cp)Nb(=NtBu)(Me₂-EDA), (Cp)Nb(=NtBu)(Et₂-EDA), (Cp)Nb(=NtBu)(nPr₂-EDA), (Cp)Nb(=NtBu)(iPr₂-EDA), (Cp)Nb(=NtBu)(nBu₂-EDA), (Cp)Nb(=NtBu)(tBu₂-EDA), (Cp)Nb(=NtBu)(nPentyl₂-EDA), (Cp)Nb(=NtBu)(tAm₂-EDA), (MeCp)Nb(=NtBu)(EDA), (MeCp)Nb(=NtBu)(Me₂-EDA), (MeCp)Nb(=NtBu)(Et₂-EDA), (MeCp)Nb(=NtBu)(nPr₂-EDA), (MeCp)Nb(=NtBu)(iPr₂-EDA), (MeCp)Nb(=NtBu)(nBu₂-EDA), (MeCp)Nb(=NtBu)(tBu₂-EDA), (MeCp)Nb(=NtBu)(nPentyl₂-EDA), (MeCp)Nb(=NtBu)(tAm₂-EDA), (EtCp)Nb(=NtBu)(EDA), (EtCp)Nb(=NtBu)(Me₂-EDA), (EtCp)Nb(=NtBu)(Et₂-EDA), (EtCp)Nb(=NtBu)(nPr₂-EDA), (EtCp)Nb(=NtBu)(iPr₂-EDA), (EtCp)Nb(=NtBu)(nBu₂-EDA), (EtCp)Nb(=NtBu)(tBu₂-EDA), (EtCp)Nb(=NtBu)(nPentyl₂-EDA), (EtCp)Nb(=NtBu)(tAm₂-EDA), (nPrCp)Nb(=NtBu)(EDA), (nPrCp)Nb(=NtBu)(Me₂-EDA), (nPrCp)Nb(=NtBu)(Et₂-EDA), (nPrCp)Nb(=NtBu)(nPr₂-EDA). (nPrCp)Nb(=NtBu)(iPr₂-EDA), (nPrCp)Nb(=NtBu)(nBu₂-EDA), (nPrCp)Nb(=NtBu)(tBu₂-EDA), (nPrCp)Nb(=NtBu)(nPentyl₂-EDA), (nPrCp)Nb(=NtBu)(tAm₂-EDA), (iPrCp)Nb(=NtBu)(EDA), (iPrCp)Nb(=NtBu)(Me₂-EDA), (iPrCp)Nb(=NtBu)(Et₂-EDA), (iPrCp)Nb(=NtBu)(nPr₂-EDA), (iPrCp)Nb(=NtBu)(iPr₂-EDA), (iPrCp)Nb(=NtBu)(nBu₂-EDA), (iPrCp)Nb(=NtBu)(tBu₂-EDA), (iPrCp)Nb(=NtBu)(nPentyl₂-EDA), (iPrCp)Nb(=NtBu)(tAm₂-EDA), (nBuCp)Nb(=NtBu)(EDA), (nBuCp)Nb(=NtBu)(Me₂-EDA), (nBuCp)Nb(=NtBu)(Et₂-EDA), (nBuCp)Nb(=NtBu)(nPr₂-EDA), (nBuCp)Nb(=NtBu)(iPr₂-EDA), (nBuCp)Nb(=NtBu)(nBu₂-EDA), (nBuCp)Nb(=NtBu)(tBu₂-EDA), (nBuCp)Nb(=NtBu)(nPentyl₂-EDA), (nBuCp)Nb(=NtBu)(tAm₂-EDA), (tBuCp)Nb(=NtBu)(EDA), (tBuCp)Nb(=NtBu)(Me₂-EDA), (tBuCp)Nb(=NtBu)(Et₂-EDA), (tBuCp)Nb(=NtBu)(nPr₂-EDA), (tBuCp)Nb(=NtBu)(iPr₂-EDA), (tBuCp)Nb(=NtBu)(nBu₂-EDA), (tBuCp)Nb(=NtBu)(tBu₂-EDA), (tBuCp)Nb(=NtBu)(nPentyl₂-EDA), (tBuCp)Nb(=NtBu)(tAm₂-EDA), (sBuCp)Nb(=NtBu)(EDA), (sBuCp)Nb(=NtBu)(Me₂-EDA), (sBuCp)Nb(=NtBu)(Et₂-EDA), (sBuCp)Nb(=NtBu)(nPr₂-EDA), (sBuCp)Nb(=NtBu)(iPr₂-EDA), (sBuCp)Nb(=NtBu)(nBu₂-EDA), (sBuCp)Nb(=NtBu)(tBu₂-EDA), (sBuCp)Nb(=NtBu)(nPentyl₂-EDA), (sBuCp)Nb(=NtBu)(tAm₂-EDA), (Di-MeCp)Nb(=NtBu)(EDA), (Di-MeCp)Nb(=NtBu)(Me₂-EDA), (Di-MeCp)Nb(=NtBu)(Et₂-EDA), (Di-MeCp)Nb(=NtBu)(nPr₂-EDA), (Di-MeCp)Nb(=NtBu)(iPr₂-EDA), (Di-MeCp)Nb(=NtBu)(nBu₂-EDA), (Di-MeCp)Nb(=NtBu)(tBu₂-EDA), (Di-MeCp)Nb(=NtBu)(nPentyl₂-EDA), (Di-MeCp)Nb(=NtBu)(tAm₂-EDA), (MeEtCp)Nb(=NtBu)(EDA), (MeEtCp)Nb(=NtBu)(Me₂-EDA), (MeEtCp)Nb(=NtBu)(Et₂-EDA), (MeEtCp)Nb(=NtBu)(nPr₂-EDA), (MeEtCp)Nb(=NtBu)(iPr₂-EDA), (MeEtCp)Nb(=NtBu)(nBu₂-EDA), (MeEtCp)Nb(=NtBu)(tBu₂-EDA), (MeEtCp)Nb(=NtBu)(nPentyl₂-EDA), (MeEtCp)Nb(=NtBu)(tAm₂-EDA), (MePrCp)Nb(=NtBu)(EDA), (MePrCp)Nb(=NtBu)(Me₂-EDA), (MePrCp)Nb(=NtBu)(Et₂-EDA), (MePrCp)Nb(=NtBu)(nPr₂-EDA), (MePrCp)Nb(=NtBu)(iPr₂-EDA), (MePrCp)Nb(=NtBu)(nBu₂-EDA), (MePrCp)Nb(=NtBu)(tBu₂-EDA), (MePrCp)Nb(=NtBu)(nPentyl₂-EDA), (MePrCp)Nb(=NtBu)(tAm₂-EDA), (Penta-MeCp)Nb(=NtBu)(EDA), (Penta-MeCp)Nb(=NtBu)(Me₂-EDA), (Penta-MeCp)Nb(=NtBu)(Et₂-EDA), (Penta-MeCp)Nb(=NtBu)(nPr₂-EDA), (Penta-MeCp)Nb(=NtBu)(iPr₂-EDA), (Penta-MeCp)Nb(=NtBu)(nBu₂-EDA), (Penta-MeCp)Nb(=NtBu)(tBu₂-EDA), (Penta-MeCp)Nb(=NtBu)(nPentyl₂-EDA), (Penta-MeCp)Nb(=NtBu)(tAm₂-EDA), (Cp)Nb(=NnPr)(EDA), (Cp)Nb(=NnPr)(Me₂-EDA), (Cp)Nb(=NnPr)(Et₂-EDA), (Cp)Nb(=NnPr)(nPr₂-EDA), (Cp)Nb(=NnPr)(iPr₂-EDA), (Cp)Nb(=NnPr)(nBu₂-EDA), (Cp)Nb(=NnPr)(tBu₂-EDA), (Cp)Nb(=NnPr)(nPentyl₂-EDA), (Cp)Nb(=NnPr)(tAm₂-EDA), (MeCp)Nb(=NnPr)(EDA), (MeCp)Nb(=NnPr)(Me₂-EDA), (MeCp)Nb(=NnPr)(Et₂-EDA), (MeCp)Nb(=NnPr)(nPr₂-EDA), (MeCp)Nb(=NnPr)(iPr₂-EDA), (MeCp)Nb(=NnPr)(nBu₂-EDA), (MeCp)Nb(=NnPr)(tBu₂-EDA), (MeCp)Nb(=NnPr)(nPentyl₂-EDA), (MeCp)Nb(=NnPr)(tAm₂-EDA), (EtCp)Nb(=NnPr)(EDA), (EtCp)Nb(=NnPr)(Me₂-EDA), (EtCp)Nb(=NnPr)(Et₂-EDA), (EtCp)Nb(=NnPr)(nPr₂-EDA), (EtCp)Nb(=NnPr)(iPr₂-EDA), (EtCp)Nb(=NnPr)(nBu₂-EDA), (EtCp)Nb(=NnPr)(tBu₂-EDA), (EtCp)Nb(=NnPr)(nPentyl₂-EDA), (EtCp)Nb(=NnPr)(tAm₂-EDA), (nPrCp)Nb(=NnPr)(EDA), (nPrCp)Nb(=NnPr)(Me₂-EDA), (nPrCp)Nb(=NnPr)(Et₂-EDA), (nPrCp)Nb(=NnPr)(nPr₂-EDA), (nPrCp)Nb(=NnPr)(iPr₂-EDA), (nPrCp)Nb(=NnPr)(nBu₂-EDA), (nPrCp)Nb(=NnPr)(tBu₂-EDA), (nPrCp)Nb(=NnPr)(nPentyl₂-EDA), (nPrCp)Nb(=NnPr)(tAm₂-EDA), (iPrCp)Nb(=NnPr)(EDA), (iPrCp)Nb(=NnPr)(Me₂-EDA), (iPrCp)Nb(=NnPr)(Et₂-EDA), (iPrCp)Nb(=NnPr)(nPr₂-EDA), (iPrCp)Nb(=NnPr)(iPr₂-EDA), (iPrCp)Nb(=NnPr)(nBu₂-EDA), (iPrCp)Nb(=NnPr)(tBu₂-EDA), (iPrCp)Nb(=NnPr)(nPentyl₂-EDA), (iPrCp)Nb(=NnPr)(tAm₂-EDA), (nBuCp)Nb(=NnPr)(EDA), (nBuCp)Nb(=NnPr)(Me₂-EDA), (nBuCp)Nb(=NnPr)(Et₂-EDA), (nBuCp)Nb(=NnPr)(nPr₂-EDA), (nBuCp)Nb(=NnPr)(iPr₂-EDA), (nBuCp)Nb(=NnPr)(nBu₂-EDA), (nBuCp)Nb(=NnPr)(tBu₂-EDA), (nBuCp)Nb(=NnPr)(nPentyl₂-EDA), (nBuCp)Nb(=NnPr)(tAm₂-EDA), (tBuCp)Nb(=NnPr)(EDA), (tBuCp)Nb(=NnPr)(Me₂-EDA), (tBuCp)Nb(=NnPr)(Et₂-EDA), (tBuCp)Nb(=NnPr)(nPr₂-EDA), (tBuCp)Nb(=NnPr)(iPr₂-EDA), (tBuCp)Nb(=NnPr)(nBu₂-EDA), (tBuCp)Nb(=NnPr)(tBu₂-EDA), (tBuCp)Nb(=NnPr)(nPentyl₂-EDA), (tBuCp)Nb(=NnPr)(tAm₂-EDA), (sBuCp)Nb(=NnPr)(EDA), (sBuCp)Nb(=NnPr)(Me₂-EDA), (sBuCp)Nb(=NnPr)(Et₂-EDA), (sBuCp)Nb(=NnPr)(nPr₂-EDA), (sBuCp)Nb(=NnPr)(iPr₂-EDA), (sBuCp)Nb(=NnPr)(nBu₂-EDA), (sBuCp)Nb(=NnPr)(tBu₂-EDA), (sBuCp)Nb(=NnPr)(nPentyl₂-EDA), (sBuCp)Nb(=NnPr)(tAm₂-EDA), (Di-MeCp)Nb(=NnPr)(EDA), (Di-MeCp)Nb(=NnPr)(Me₂-EDA), (Di-MeCp)Nb(=NnPr)(Et₂-EDA), (Di-MeCp)Nb(=NnPr)(nPr₂-EDA), (Di-MeCp)Nb(=NnPr)(iPr₂-EDA), (Di-MeCp)Nb(=NnPr)(nBu₂-EDA), (Di-MeCp)Nb(=NnPr)(tBu₂-EDA), (Di-MeCp)Nb(=NnPr)(nPentyl₂-EDA), (Di-MeCp)Nb(=NnPr)(tAm₂-EDA), (MeEtCp)Nb(=NnPr)(EDA), (MeEtCp)Nb(=NnPr)(Me₂-EDA). (MeEtCp)Nb(=NnPr)(Et₂-EDA), (MeEtCp)Nb(=NnPr)(nPr₂-EDA), (MeEtCp)Nb(=NnPr)(iPr₂-EDA), (MeEtCp)Nb(=NnPr)(nBu₂-EDA), (MeEtCp)Nb(=NnPr)(tBu₂-EDA), (MeEtCp)Nb(=NnPr)(nPentyl₂-EDA), (MeEtCp)Nb(=NnPr)(tAm₂-EDA), (MePrCp)Nb(=NnPr)(EDA), (MePrCp)Nb(=NnPr)(Me₂-EDA), (MePrCp)Nb(=NnPr)(Et₂-EDA), (MePrCp)Nb(=NnPr)(nPr₂-EDA), (MePrCp)Nb(=NnPr)(iPr₂-EDA), (MePrCp)Nb(=NnPr)(nBu₂-EDA), (MePrCp)Nb(=NnPr)(tBu₂-EDA), (MePrCp)Nb(=NnPr)(nPentyl₂-EDA), (MePrCp)Nb(=NnPr)(tAm₂-EDA (Penta-MeCp)Nb(=NnPr)(EDA), (Penta-MeCp)Nb(=NnPr)(Me₂-EDA), (Penta-MeCp)Nb(=NnPr)(Et₂-EDA), (Penta-MeCp)Nb(=NnPr)(nPr₂-EDA), (Penta-MeCp)Nb(=NnPr)(iPr₂-EDA), (Penta-MeCp)Nb(=NnPr)(nBu₂-EDA), (Penta-MeCp)Nb(=NnPr)(tBu₂-EDA), (Penta-MeCp)Nb(=NnPr)(nPentyl₂-EDA) or (Penta-MeCp)Nb(=NnPr)(tAm₂-EDA).
the Group V (five)-containing film being an Nb₂O₅ film or an NbN film;
the substrate being a Si wafer;
the substrate being a crystalline silicon layer;
the substrate being a powder substrate;
the vapor deposition process being an ALD process or a CVD process;
the vapor deposition process being a PEALD process or a spatial ALD process; and
a deposition temperature ranging from approximately 50° C. and approximately 600° C.

Also disclosed is a Group V (five)-containing film forming composition for a vapor deposition process comprising a precursor having the formula:

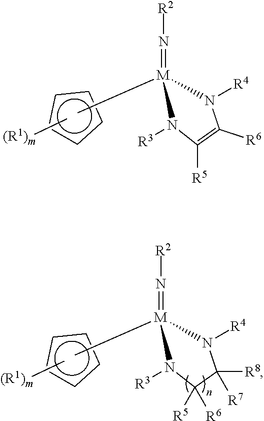

wherein M is Group V (five) element, vanadium (V), niobium (Nb), or tantalum (Ta);
R¹ to R⁸ each is H, a C₁-C₆ alkyl group, a fluoro group, an alkylsilyl group, a germyl group, an alkylamide or an alkylsilylamide; m=1 to 5, n=1 to 5. The disclosed methods may include one or more of the following aspects:
R¹ to R⁸ each being independently H, Me, Et, nPr, iPr, tBu, sBu, iBu, nBu, tAmyl, SiMe₃, SiMe₂H, or SiH₂Me;
the precursor being Niobium tButyl Imido Cyclopentadienyl tAmyl-Diazadienyl, CpNb(=NtBu)(tAm₂-DAD);
the Group V (five)-containing film forming composition comprising between approximately 95% w/w and approximately 100.0% w/w of the precursor;
the Group V (five)-containing film forming composition comprising between 99.0% w/w to 100.0% w/w of the precursor;
the Group V (five)-containing film forming composition comprising between approximately 0.0% w/w and approximately 5.0% w/w impurities.

Also disclosed is a method of forming an Nb₂O₅ film or coating by an ALD process on a substrate in a reaction chamber, the method comprising the steps of:
a) exposing the substrate to a vapor of Niobium tButyl Imido Cyclopentadienyl tAmyl-Diazadienyl (CpNb(=NtBu)(tAm₂-DAD));
b) exposing the substrate to an oxidizer; and
c) repeating the steps of a) and b) until a desired thickness of the Nb₂O₅ film is deposited on the substrate using the ALD process. The disclosed methods may include one or more of the following aspects:
further comprising the steps of
   introducing an inert gas to purge th reaction chamber following the steps a) and b), respectively, to separate each exposure;
the substrate being a powder;
the powder comprising one or more of NMC (Lithium Nickel Manganese Cobalt Oxide), LCO (Lithium Cobalt Oxide), LFP (Lithium Iron Phosphate), and other battery cathode materials.

### NOTATION AND NOMENCLATURE

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 30° C.

The term “ambient temperature” refers to an environment temperature approximately 20° C. to approximately 30° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, Al₂O₃ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the Group V (five)-containing film.

The term “aspect ratio” refers to a ratio of the height of a trench (or aperture) to the width of the trench (or the diameter of the aperture).

The term “high aspect ratio” refers to an aspect ratio larger than approximately 2:1, preferably an aspect ratio ranging from approximately 2:1 to approximately 200:1.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “aperture”, “via”, “hole” and “trench” may be used interchangeably to refer to an opening formed in a semiconductor structure.

As used herein, the abbreviation “NAND” refers to a “Negative AND” or “Not AND” (electronic logic gate); the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

The term “film-forming composition” refers to a composition used for deposition of a film. The film-forming composition may include, but is not limited to, a precursor, a solvent and/or a carrier gas. Furthermore, the film-forming composition may include, but is not limited to, a precursor, optionally a solvent, optionally a carrier gas, and optionally one or more co-reactant(s). Herein, the precursor may be supplied either in a neat form or in a blend with a suitable solvent. The precursor may be present in varying concentrations in the solvent. Alternatively, the precursor may be vaporized by passing a carrier gas into a container that contains the precursor or by bubbling the carrier gas into the precursor. The carrier gas and precursor are then introduced into a reactor as a vapor. The co-reactant may be an oxidizer, a reducing agent, a dilute gas, an additive, an inhibitor, an additional or a secondary precursor, etc., for assisting in formation of the film. Here an inert gas selected from N₂, He, Ar, Kr, Xe may be used as the carrier gas and/or the dilute gas.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl croups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl croup; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tent-amyl group, also known as 1,1-dimethylpropyl.

Please note that the metal-containing (V, Nb and Ta) films or layers deposited, such as niobium oxide or niobium nitride, may be listed throughout the specification and claims without reference to their proper stoichiometry (e.g., NbO=Nb₂O₅). These layers may also contain Hydrogen, typically from 0 atomic % to 15 atomic %. However, since not routinely measured, any film compositions given ignore their H content, unless explicitly stated otherwise. Furthermore, the concentration of hydrogen may be further tuned by performing post deposition annealing to obtained desired thin film properties.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

As used herein, the formula, (R³R⁴R⁵R⁶R⁷Cp)Nb(=NR¹)(R²₂-DAD), is represented by the following structure:

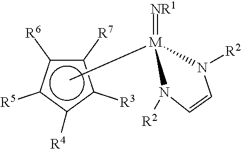

wherein DAD=Diazadiene; R¹=tBu or nPr; R²=Me, Et, nPr, iPr, nBu, tBu, nPentyl or tAm; R³, R⁴, R⁵, R⁶ and R⁷ each is Independently H, Me, Et, nPr, iPr, nBu, tBu or sBu.

As used herein, the formula, (R³R⁴R⁵R⁶R⁷Cp)Nb(=NR¹)(R²₂-EDA), is represented by the following structure:

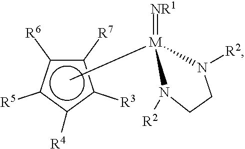

wherein EDA is Ethylenediamine; R¹ is tBu or nPr; R² is Me, Et, nPr, iPr, nBu, tBu, nPentyl or tAm; R³, R⁴, R⁵, R⁶ and R⁷ each is Independently H, Me, Et, nPr, iPr, nBu, tBu or sBu.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation,”

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term which means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 is a Thermo Gravimetric Analysis (TGA) graph demonstrating the percentage of weight with increasing temperature of Niobium tButyl imido cyclopentadienyl tAmyl-diazadienyl, CpNb(=NtBu)(tAm₂-DAD);

FIG. 2 is a Differential scanning calorimetry (DSC) of CpNb(=NtBu)(tAm₂-DAD);

FIG. 3 is ALD window of CpNb(=NtBu)(tAm₂-DAD);

FIG. 4a is a full image of step coverage of patterned wafer of Nb₂O₅ film at 325° C. by SEM;

FIG. 4b is a top image of FIG. 4a;

FIG. 4c is a bottom image of FIG. 4a; and

FIG. 5 is a XPS depth profile plot of Nb₂O₅ film at 325° C.

### DESCRIPTION OF PREFERRED EMBODIMENTS

Disclosed are Group V (five) (V, Nb, Ta) metal containing films forming compositions, methods of synthesizing the same, and methods of forming Group V metal containing films on one or more substrates via ALD (atomic layer deposition processes) using the Group V metal containing film forming compositions.

The disclosed Group V element-containing film forming compositions comprise Group V element-containing precursors having the formula:

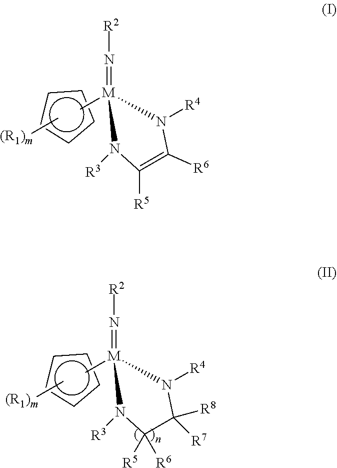

wherein M is Group V (five) element, vanadium (V), niobium (Nb), or tantalum (Ta); R¹ to R⁸ each is H, a C₁-C₆ alkyl group, a fluoro group, an alkylsilyl group, a germyl group, an alkylamide or an alkylsilylamide; m=1 to 5, n=1 to 5. As illustrated in the above formula, the nitrogen atoms and a cyclopentadienyl ring may be bonded to the center Group V atom M, resulting in a tetracoordinate M(V) center. The resulting geometry may be pseudo tetrahedral.

The disclosed Group V element-containing precursors offer high thermal stability by chelating effect of bidentate ligand which has linkage between two amines, when compared to NbCp(=NtBu)(NMe₂)₂ that has no bidentate ligand.

Exemplary Group V element-containing precursors from formula (I) include: (R³⁻⁷Cp)Nb(=NR¹)(R²₂-DAD),

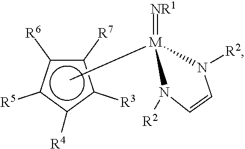

wherein DAD=Diazadiene; R¹=tBu or nPr; R²=Me, Et, nPr, iPr, nBu, tBu, nPentyl or tAm; R³, R⁴, R⁵, R⁶ and R⁷ each is Independently H, Me, Et, nPr, iPr, nBu, tBu or sBu. Here R³⁻⁷ represents R³R⁴R⁵R⁶R⁷. More specifically, (R³⁻⁷Cp)Nb(=NR¹)(R²₂-DAD) includes (Cp)Nb(=NtBu)(Me₂-DAD), (Cp)Nb(=NtBu)(Et₂-DAD), (Cp)Nb(=NtBu)(nPr₂-DAD), (Cp)Nb(=NtBu)(iPr₂-DAD), (Cp)Nb(=NtBu)(nBu₂-DAD), (Cp)Nb(=NtBu)(tBu₂-DAD), (Cp)Nb(=NtBu)(nPentyl₂-DAD), (Cp)Nb(=NtBu)(tAm₂-DAD), (MeCp)Nb(=NtBu)(Me₂-DAD), (MeCp)Nb(=NtBu)(Et₂-DAD), (MeCp)Nb(=NtBu)(nPr₂-DAD), (MeCp)Nb(=NtBu)(iPr₂-DAD), (MeCp)Nb(=NtBu)(nBu₂-DAD), (MeCp)Nb(=NtBu)(tBu₂-DAD), (MeCp)Nb(=NtBu)(nPentyl₂-DAD), (MeCp)Nb(=NtBu)(tAm₂-DAD), (EtCp)Nb(=NtBu)(Me₂-DAD), (EtCp)Nb(=NtBu)(Et₂-DAD), (EtCp)Nb(=NtBu)(nPr₂-DAD), (EtCp)Nb(=NtBu)(iPr₂-DAD), (EtCp)Nb(=NtBu)(nBu₂-DAD), (EtCp)Nb(=NtBu)(tBu₂-DAD), (EtCp)Nb(=NtBu)(nPentyl₂-DAD), (EtCp)Nb(=NtBu)(tAm₂-DAD), (nPrCp)Nb(=NtBu)(Me₂-DAD), (nPrCp)Nb(=NtBu)(Et₂-DAD), (nPrCp)Nb(=NtBu)(nPr₂-DAD), (nPrCp)Nb(=NtBu)(iPr₂-DAD), (nPrCp)Nb(=NtBu)(nBu₂-DAD), (nPrCp)Nb(=NtBu)(tBu₂-DAD), (nPrCp)Nb(=NtBu)(nPentyl₂-DAD), (nPrCp)Nb(=NtBu)(tAm₂-DAD), (iPrCp)Nb(=NtBu)(Me₂-DAD), (iPrCp)Nb(=NtBu)(Et₂-DAD), (iPrCp)Nb(=NtBu)(nPr₂-DAD), (iPrCp)Nb(=NtBu)(iPr₂-DAD), (iPrCp)Nb(=NtBu)(nBu₂-DAD), (iPrCp)Nb(=NtBu)(tBu₂-DAD), (iPrCp)Nb(=NtBu)(nPentyl₂-DAD), (iPrCp)Nb(=NtBu)(tAm₂-DAD), (nBuCp)Nb(=NtBu)(Me₂-DAD), (nBuCp)Nb(=NtBu)(Et₂-DAD), (nBuCp)Nb(=NtBu)(nPr₂-DAD), (nBuCp)Nb(=NtBu)(iPr₂-DAD), (nBuCp)Nb(=NtBu)(nBu₂-DAD), (nBuCp)Nb(=NtBu)(tBu₂-DAD), (nBuCp)Nb(=NtBu)(nPentyl₂-DAD), (nBuCp)Nb(=NtBu)(tAm₂-DAD), (tBuCp)Nb(=NtBu)(Me₂-DAD), (tBuCp)Nb(=NtBu)(Et₂-DAD), (tBuCp)Nb(=NtBu)(nPr₂-DAD), (tBuCp)Nb(=NtBu)(iPr₂-DAD), (tBuCp)Nb(=NtBu)(nBu₂-DAD), (tBuCp)Nb(=NtBu)(tBu₂-DAD), (tBuCp)Nb(=NtBu)(nPentyl₂-DAD), (tBuCp)Nb(=NtBu)(tAm₂-DAD), (sBuCp)Nb(=NtBu)(Me₂-DAD), (sBuCp)Nb(=NtBu)(Et₂-DAD), (sBuCp)Nb(=NtBu)(nPr₂-DAD), (sBuCp)Nb(=NtBu)(iPr₂-DAD), (sBuCp)Nb(=NtBu)(nBu₂-DAD), (sBuCp)Nb(=NtBu)(tBu₂-DAD), (sBuCp)Nb(=NtBu)(nPentyl₂-DAD), (sBuCp)Nb(=NtBu)(tAm₂-DAD), (Di-MeCp)Nb(=NtBu)(Me₂-DAD), (Di-MeCp)Nb(=NtBu)(Et₂-DAD), (Di-MeCp)Nb(=NtBu)(nPr₂-DAD), (Di-MeCp)Nb(=NtBu)(iPr₂-DAD), (Di-MeCp)Nb(=NtBu)(nBu₂-DAD), (Di-MeCp)Nb(=NtBu)(tBu₂-DAD), (Di-MeCp)Nb(=NtBu)(nPentyl₂-DAD), (Di-MeCp)Nb(=NtBu)(tAm₂-DAD), (MeEtCp)Nb(=NtBu)(Me₂-DAD), (MeEtCp)Nb(=NtBu)(Et₂-DAD), (MeEtCp)Nb(=NtBu)(nPr₂-DAD), (MeEtCp)Nb(=NtBu)(iPr₂-DAD), (MeEtCp)Nb(=NtBu)(nBu₂-DAD), (MeEtCp)Nb(=NtBu)(tBu₂-DAD), (MeEtCp)Nb(=NtBu)(nPentyl₂-DAD), (MeEtCp)Nb(=NtBu)(tAm₂-DAD), (MePrCp)Nb(=NtBu)(Me₂-DAD), (MePrCp)Nb(=NtBu)(Et₂-DAD), (MePrCp)Nb(=NtBu)(nPr₂-DAD), (MePrCp)Nb(=NtBu)(iPr₂-DAD), (MePrCp)Nb(=NtBu)(nBu₂-DAD), (MePrCp)Nb(=NtBu)(tBu₂-DAD), (MePrCp)Nb(=NtBu)(nPentyl₂-DAD), (MePrCp)Nb(=NtBu)(tAm₂-DAD), (Penta-MeCp)Nb(=NtBu)(Me₂-DAD), (Penta-MeCp)Nb(=NtBu)(Et₂-DAD), (Penta-MeCp)Nb(=NtBu)(nPr₂-DAD), (Penta-MeCp)Nb(=NtBu)(iPr₂-DAD), (Penta-MeCp)Nb(=NtBu)(nBu₂-DAD), (Penta-MeCp)Nb(=NtBu)(tBu₂-DAD), (Penta-MeCp)Nb(=NtBu)(nPentyl₂-DAD), (Penta-MeCp)Nb(=NtBu)(tAm₂-DAD), (Cp)Nb(=NnPr)(Me₂-DAD), (Cp)Nb(=NnPr)(Et₂-DAD), (Cp)Nb(=NnPr)(nPr₂-DAD), (Cp)Nb(=NnPr)(iPr₂-DAD), (Cp)Nb(=NnPr)(nBu₂-DAD), (Cp)Nb(=NnPr)(tBu₂-DAD), (Cp)Nb(=NnPr)(nPentyl₂-DAD), (Cp)Nb(=NnPr)(tAm₂-DAD), (MeCp)Nb(=NnPr)(Me₂-DAD), (MeCp)Nb(=NnPr)(Et₂-DAD), (MeCp)Nb(=NnPr)(nPr₂-DAD), (MeCp)Nb(=NnPr)(iPr₂-DAD), (MeCp)Nb(=NnPr)(nBu₂-DAD), (MeCp)Nb(=NnPr)(tBu₂-DAD), (MeCp)Nb(=NnPr)(nPentyl₂-DAD), (MeCp)Nb(=NnPr)(tAm₂-DAD), (EtCp)Nb(=NnPr)(Me₂-DAD), (EtCp)Nb(=NnPr)(Et₂-DAD), (EtCp)Nb(=NnPr)(nPr₂-DAD), (EtCp)Nb(=NnPr)(iPr₂-DAD), (EtCp)Nb(=NnPr)(nBu₂-DAD), (EtCp)Nb(=NnPr)(tBu₂-DAD), (EtCp)Nb(=NnPr)(nPentyl₂-DAD), (EtCp)Nb(=NnPr)(tAm₂-DAD), (nPrCp)Nb(=NnPr)(Me₂-DAD), (nPrCp)Nb(=NnPr)(Et₂-DAD), (nPrCp)Nb(=NnPr)(nPr₂-DAD), (nPrCp)Nb(=NnPr)(iPr₂-DAD), (nPrCp)Nb(=NnPr)(nBu₂-DAD), (nPrCp)Nb(=NnPr)(tBu₂-DAD), (nPrCp)Nb(=NnPr)(nPentyl₂-DAD), (nPrCp)Nb(=NnPr)(tAm₂-DAD), (iPrCp)Nb(=NnPr)(Me₂-DAD), (iPrCp)Nb(=NnPr)(Et₂-DAD), (iPrCp)Nb(=NnPr)(nPr₂-DAD), (iPrCp)Nb(=NnPr)(iPr₂-DAD), (iPrCp)Nb(=NnPr)(nBu₂-DAD), (iPrCp)Nb(=NnPr)(tBu₂-DAD), (iPrCp)Nb(=NnPr)(nPentyl₂-DAD), (iPrCp)Nb(=NnPr)(tAm₂-DAD), (nBuCp)Nb(=NnPr)(Me₂-DAD), (nBuCp)Nb(=NnPr)(Et₂-DAD), (nBuCp)Nb(=NnPr)(nPr₂-DAD), (nBuCp)Nb(=NnPr)(iPr₂-DAD), (nBuCp)Nb(=NnPr)(nBu₂-DAD), (nBuCp)Nb(=NnPr)(tBu₂-DAD), (nBuCp)Nb(=NnPr)(nPentyl₂-DAD), (nBuCp)Nb(=NnPr)(tAm₂-DAD), (tBuCp)Nb(=NnPr)(Me₂-DAD), (tBuCp)Nb(=NnPr)(Et₂-DAD), (tBuCp)Nb(=NnPr)(nPr₂-DAD), (tBuCp)Nb(=NnPr)(iPr₂-DAD), (tBuCp)Nb(=NnPr)(nBu₂-DAD), (tBuCp)Nb(=NnPr)(tBu₂-DAD), (tBuCp)Nb(=NnPr)(nPentyl₂-DAD), (tBuCp)Nb(=NnPr)(tAm₂-DAD), (sBuCp)Nb(=NnPr)(Me₂-DAD), (sBuCp)Nb(=NnPr)(Et₂-DAD), (sBuCp)Nb(=NnPr)(nPr₂-DAD), (sBuCp)Nb(=NnPr)(iPr₂-DAD), (sBuCp)Nb(=NnPr)(nBu₂-DAD), (sBuCp)Nb(=NnPr)(tBu₂-DAD), (sBuCp)Nb(=NnPr)(nPentyl₂-DAD), (sBuCp)Nb(=NnPr)(tAm₂-DAD), (Di-MeCp)Nb(=NnPr)(Me₂-DAD), (Di-MeCp)Nb(=NnPr)(Et₂-DAD), (Di-MeCp)Nb(=NnPr)(nPr₂-DAD), (Di-MeCp)Nb(=NnPr)(iPr₂-DAD), (Di-MeCp)Nb(=NnPr)(nBu₂-DAD), (Di-MeCp)Nb(=NnPr)(tBu₂-DAD), (Di-MeCp)Nb(=NnPr)(nPentyl₂-DAD), (Di-MeCp)Nb(=NnPr)(tAm₂-DAD), (MeEtCp)Nb(=NnPr)(Me₂-DAD), (MeEtCp)Nb(=NnPr)(Et₂-DAD), (MeEtCp)Nb(=NnPr)(nPr₂-DAD), (MeEtCp)Nb(=NnPr)(iPr₂-DAD), (MeEtCp)Nb(=NnPr)(nBu₂-DAD), (MeEtCp)Nb(=NnPr)(tBu₂-DAD), (MeEtCp)Nb(=NnPr)(nPentyl₂-DAD), (MeEtCp)Nb(=NnPr)(tAm₂-DAD), (MePrCp)Nb(=NnPr)(Me₂-DAD), (MePrCp)Nb(=NnPr)(Et₂-DAD), (MePrCp)Nb(=NnPr)(nPr₂-DAD), (MePrCp)Nb(=NnPr)(iPr₂-DAD), (MePrCp)Nb(=NnPr)(nBu₂-DAD), (MePrCp)Nb(=NnPr)(tBu₂-DAD), (MePrCp)Nb(=NnPr)(nPentyl₂-DAD), (MePrCp)Nb(=NnPr)(tAm₂-DAD), (Penta-MeCp)Nb(=NnPr)(Me₂-DAD), (Penta-MeCp)Nb(=NnPr)(Et₂-DAD), (Penta-MeCp)Nb(=NnPr)(nPr₂-DAD), (Penta-MeCp)Nb(=NnPr)(iPr₂-DAD), (Penta-MeCp)Nb(=NnPr)(nBu₂-DAD), (Penta-MeCp)Nb(=NnPr)(tBu₂-DAD), (Penta-MeCp)Nb(=NnPr)(nPentyl₂-DAD), or (Penta-MeCp)Nb(=NnPr)(tAm₂-DAD).

Exemplary Group V (five) element-containing precursors from formula (H) include: (R³⁻⁷Cp)Nb(=NR¹)(R²₂-EDA),

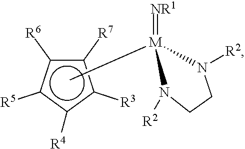

wherein EDA is Ethylenediamine: R¹=tBu or nPr; R²=Me, Et, nPr, iPr, nBu, tBu, nPentyl or tAm; R³, R⁴, R⁵, R⁶ and R⁷ each is independently H, Me, Et, nPr, iPr, nBu, tBu or sBu. Here R³⁻⁷ represents R³R⁴R⁵R⁶R⁷. More specifically, (R³⁻⁷Cp)Nb(=NR¹)(R²₂-EDA) includes (Cp)Nb(=NtBu)(EDA), (Cp)Nb(=NtBu)(Me₂-EDA), (Cp)Nb(=NtBu)(Et₂-EDA), (Cp)Nb(=NtBu)(nPr₂-EDA), (Cp)Nb(=NtBu)(iPr₂-EDA), (Cp)Nb(=NtBu)(nBu₂-EDA), (Cp)Nb(=NtBu)(tBu₂-EDA), (Cp)Nb(=NtBu)(nPentyl₂-EDA), (Cp)Nb(=NtBu)(tAm₂-EDA), (MeCp)Nb(=NtBu)(EDA), (MeCp)Nb(=NtBu)(Me₂-EDA), (MeCp)Nb(=NtBu)(Et₂-EDA), (MeCp)Nb(=NtBu)(nPr₂-EDA), (MeCp)Nb(=NtBu)(iPr₂-EDA), (MeCp)Nb(=NtBu)(nBu₂-EDA), (MeCp)Nb(=NtBu)(tBu₂-EDA), (MeCp)Nb(=NtBu)(nPentyl₂-EDA), (MeCp)Nb(=NtBu)(tAm₂-EDA), (EtCp)Nb(=NtBu)(EDA), (EtCp)Nb(=NtBu)(Me₂-EDA), (EtCp)Nb(=NtBu)(Et₂-EDA), (EtCp)Nb(=NtBu)(nPr₂-EDA), (EtCp)Nb(=NtBu)(iPr₂-EDA), (EtCp)Nb(=NtBu)(nBu₂-EDA), (EtCp)Nb(=NtBu)(tBu₂-EDA), (EtCp)Nb(=NtBu)(nPentyl₂-EDA), (EtCp)Nb(=NtBu)(tAm₂-EDA), (nPrCp)Nb(=NtBu)(EDA), (nPrCp)Nb(=NtBu)(Me₂-EDA), (nPrCp)Nb(=NtBu)(Et₂-EDA), (nPrCp)Nb(=NtBu)(nPr₂-EDA), (nPrCp)Nb(=NtBu)(iPr₂-EDA), (nPrCp)Nb(=NtBu)(nBu₂-EDA), (nPrCp)Nb(=NtBu)(tBu₂-EDA), (nPrCp)Nb(=NtBu)(nPentyl₂-EDA), (nPrCp)Nb(=NtBu)(tAm₂-EDA). (iPrCp)Nb(=NtBu)(EDA), (iPrCp)Nb(=NtBu)(Me₂-EDA), (iPrCp)Nb(=NtBu)(Et₂-EDA), (iPrCp)Nb(=NtBu)(nPr₂-EDA), (iPrCp)Nb(=NtBu)(iPr₂-EDA), (iPrCp)Nb(=NtBu)(nBu₂-EDA), (iPrCp)Nb(=NtBu)(tBu₂-EDA), (iPrCp)Nb(=NtBu)(nPentyl₂-EDA), (iPrCp)Nb(=NtBu)(tAm₂-EDA), (nBuCp)Nb(=NtBu)(EDA), (nBuCp)Nb(=NtBu)(Me₂-EDA), (nBuCp)Nb(=NtBu)(Et₂-EDA), (nBuCp)Nb(=NtBu)(nPr₂-EDA), (nBuCp)Nb(=NtBu)(iPr₂-EDA), (nBuCp)Nb(=NtBu)(nBu₂-EDA), (nBuCp)Nb(=NtBu)(tBu₂-EDA). (nBuCp)Nb(=NtBu)(nPentyl₂-EDA), (nBuCp)Nb(=NtBu)(tAm₂-EDA), (tBuCp)Nb(=NtBu)(EDA), (tBuCp)Nb(=NtBu)(Me₂-EDA), (tBuCp)Nb(=NtBu)(Et₂-EDA), (tBuCp)Nb(=NtBu)(nPr₂-EDA), (tBuCp)Nb(=NtBu)(iPr₂-EDA), (tBuCp)Nb(=NtBu)(nBu₂-EDA), (tBuCp)Nb(=NtBu)(tBu₂-EDA), (tBuCp)Nb(=NtBu)(nPentyl₂-EDA), (tBuCp)Nb(=NtBu)(tAm₂-EDA), (sBuCp)Nb(=NtBu)(EDA), (sBuCp)Nb(=NtBu)(Me₂-EDA), (sBuCp)Nb(=NtBu)(Et₂-EDA), (sBuCp)Nb(=NtBu)(nPr₂-EDA), (sBuCp)Nb(=NtBu)(iPr₂-EDA), (sBuCp)Nb(=NtBu)(nBu₂-EDA), (sBuCp)Nb(=NtBu)(tBu₂-EDA), (sBuCp)Nb(=NtBu)(nPentyl₂-EDA), (sBuCp)Nb(=NtBu)(tAm₂-EDA), (Di-MeCp)Nb(=NtBu)(EDA), (Di-MeCp)Nb(=NtBu)(Me₂-EDA), (Di-MeCp)Nb(=NtBu)(Et₂-EDA), (Di-MeCp)Nb(=NtBu)(nPr₂-EDA), (Di-MeCp)Nb(=NtBu)(iPr₂-EDA), (Di-MeCp)Nb(=NtBu)(nBu₂-EDA), (Di-MeCp)Nb(=NtBu)(tBu₂-EDA), (Di-MeCp)Nb(=NtBu)(nPentyl₂-EDA), (Di-MeCp)Nb(=NtBu)(tAm₂-EDA), (MeEtCp)Nb(=NtBu)(EDA), (MeEtCp)Nb(=NtBu)(Me₂-EDA), (MeEtCp)Nb(=NtBu)(Et₂-EDA), (MeEtCp)Nb(=NtBu)(nPr₂-EDA), (MeEtCp)Nb(=NtBu)(iPr₂-EDA), (MeEtCp)Nb(=NtBu)(nBu₂-EDA), (MeEtCp)Nb(=NtBu)(tBu₂-EDA), (MeEtCp)Nb(=NtBu)(nPentyl₂-EDA), (MeEtCp)Nb(=NtBu)(tAm₂-EDA), (MePrCp)Nb(=NtBu)(EDA), (MePrCp)Nb(=NtBu)(Me₂-EDA), (MePrCp)Nb(=NtBu)(Et₂-EDA), (MePrCp)Nb(=NtBu)(nPr₂-EDA), (MePrCp)Nb(=NtBu)(iPr₂-EDA), (MePrCp)Nb(=NtBu)(nBu₂-EDA), (MePrCp)Nb(=NtBu)(tBu₂-EDA), (MePrCp)Nb(=NtBu)(nPentyl₂-EDA), (MePrCp)Nb(=NtBu)(tAm₂-EDA), (Penta-MeCp)Nb(=NtBu)(EDA), (Penta-MeCp)Nb(=NtBu)(Me₂-EDA), (Penta-MeCp)Nb(=NtBu)(Et₂-EDA), (Penta-MeCp)Nb(=NtBu)(nPr₂-EDA), (Penta-MeCp)Nb(=NtBu)(iPr₂-EDA), (Penta-MeCp)Nb(=NtBu)(nBu₂-EDA), (Penta-MeCp)Nb(=NtBu)(tBu₂-EDA), (Penta-MeCp)Nb(=NtBu)(nPentyl₂-EDA), (Penta-MeCp)Nb(=NtBu)(tAm₂-EDA), (Cp)Nb(=NnPr)(EDA), (Cp)Nb(=NnPr)(Me₂-EDA), (Cp)Nb(=NnPr)(Et₂-EDA), (Cp)Nb(=NnPr)(nPr₂-EDA), (Cp)Nb(=NnPr)(iPr₂-EDA), (Cp)Nb(=NnPr)(nBu₂-EDA), (Cp)Nb(=NnPr)(tBu₂-EDA), (Cp)Nb(=NnPr)(nPentyl₂-EDA), (Cp)Nb(=NnPr)(tAm₂-EDA), (MeCp)Nb(=NnPr)(EDA), (MeCp)Nb(=NnPr)(Me₂-EDA), (MeCp)Nb(=NnPr)(Et₂-EDA), (MeCp)Nb(=NnPr)(nPr₂-EDA), (MeCp)Nb(=NnPr)(iPr₂-EDA), (MeCp)Nb(=NnPr)(nBu₂-EDA), (MeCp)Nb(=NnPr)(tBu₂-EDA), (MeCp)Nb(=NnPr)(nPentyl₂-EDA), (MeCp)Nb(=NnPr)(tAm₂-EDA), (EtCp)Nb(=NnPr)(EDA), (EtCp)Nb(=NnPr)(Me₂-EDA), (EtCp)Nb(=NnPr)(Et₂-EDA), (EtCp)Nb(=NnPr)(nPr₂-EDA), (EtCp)Nb(=NnPr)(iPr₂-EDA), (EtCp)Nb(=NnPr)(nBu₂-EDA), (EtCp)Nb(=NnPr)(tBu₂-EDA), (EtCp)Nb(=NnPr)(nPentyl₂-EDA), (EtCp)Nb(=NnPr)(tAm₂-EDA), (nPrCp)Nb(=NnPr)(EDA), (nPrCp)Nb(=NnPr)(Me₂-EDA), (nPrCp)Nb(=NnPr)(Et₂-EDA), (nPrCp)Nb(=NnPr)(nPr₂-EDA), (nPrCp)Nb(=NnPr)(iPr₂-EDA), (nPrCp)Nb(=NnPr)(nBu₂-EDA), (nPrCp)Nb(=NnPr)(tBu₂-EDA), (nPrCp)Nb(=NnPr)(nPentyl₂-EDA), (nPrCp)Nb(=NnPr)(tAm₂-EDA), (iPrCp)Nb(=NnPr)(EDA), (iPrCp)Nb(=NnPr)(Me₂-EDA), (iPrCp)Nb(=NnPr)(Et₂-EDA), (iPrCp)Nb(=NnPr)(nPr₂-EDA), (iPrCp)Nb(=NnPr)(iPr₂-EDA), (iPrCp)Nb(=NnPr)(nBu₂-EDA), (iPrCp)Nb(=NnPr)(tBu₂-EDA), (iPrCp)Nb(=NnPr)(nPentyl₂-EDA), (iPrCp)Nb(=NnPr)(tAm₂-EDA), (nBuCp)Nb(=NnPr)(EDA), (nBuCp)Nb(=NnPr)(Me₂-EDA), (nBuCp)Nb(=NnPr)(Et₂-EDA), (nBuCp)Nb(=NnPr)(nPr₂-EDA), (nBuCp)Nb(=NnPr)(iPr₂-EDA), (nBuCp)Nb(=NnPr)(nBu₂-EDA), (nBuCp)Nb(=NnPr)(tBu₂-EDA), (nBuCp)Nb(=NnPr)(nPentyl₂-EDA), (nBuCp)Nb(=NnPr)(tAm₂-EDA), (tBuCp)Nb(=NnPr)(EDA), (tBuCp)Nb(=NnPr)(Me₂-EDA), (tBuCp)Nb(=NnPr)(Et₂-EDA), (tBuCp)Nb(=NnPr)(nPr₂-EDA), (tBuCp)Nb(=NnPr)(iPr₂-EDA), (tBuCp)Nb(=NnPr)(nBu₂-EDA), (tBuCp)Nb(=NnPr)(tBu₂-EDA), (tBuCp)Nb(=NnPr)(nPentyl₂-EDA), (tBuCp)Nb(=NnPr)(tAm₂-EDA), (sBuCp)Nb(=NnPr)(EDA), (sBuCp)Nb(=NnPr)(Me₂-EDA), (sBuCp)Nb(=NnPr)(Et₂-EDA), (sBuCp)Nb(=NnPr)(nPr₂-EDA), (sBuCp)Nb(=NnPr)(iPr₂-EDA), (sBuCp)Nb(=NnPr)(nBu₂-EDA), (sBuCp)Nb(=NnPr)(tBu₂-EDA), (sBuCp)Nb(=NnPr)(nPentyl₂-EDA), (sBuCp)Nb(=NnPr)(tAm₂-EDA), (Di-MeCp)Nb(=NnPr)(EDA), (Di-MeCp)Nb(=NnPr)(Me₂-EDA), (Di-MeCp)Nb(=NnPr)(Et₂-EDA), (Di-MeCp)Nb(=NnPr)(nPr₂-EDA), (Di-MeCp)Nb(=NnPr)(iPr₂-EDA), (Di-MeCp)Nb(=NnPr)(nBu₂-EDA), (Di-MeCp)Nb(=NnPr)(tBu₂-EDA), (Di-MeCp)Nb(=NnPr)(nPentyl₂-EDA), (Di-MeCp)Nb(=NnPr)(tAm₂-EDA), (MeEtCp)Nb(=NnPr)(EDA), (MeEtCp)Nb(=NnPr)(Me₂-EDA), (MeEtCp)Nb(=NnPr)(Et₂-EDA), (MeEtCp)Nb(=NnPr)(nPr₂-EDA), (MeEtCp)Nb(=NnPr)(iPr₂-EDA), (MeEtCp)Nb(=NnPr)(nBu₂-EDA), (MeEtCp)Nb(=NnPr)(tBu₂-EDA), (MeEtCp)Nb(=NnPr)(nPentyl₂-EDA), (MeEtCp)Nb(=NnPr)(tAm₂-EDA), (MePrCp)Nb(=NnPr)(EDA), (MePrCp)Nb(=NnPr)(Me₂-EDA), (MePrCp)Nb(=NnPr)(Et₂-EDA), (MePrCp)Nb(=NnPr)(nPr₂-EDA), (MePrCp)Nb(=NnPr)(iPr₂-EDA), (MePrCp)Nb(=NnPr)(nBu₂-EDA), (MePrCp)Nb(=NnPr)(tBu₂-EDA), (MePrCp)Nb(=NnPr)(nPentyl₂-EDA), (MePrCp)Nb(=NnPr)(tAm₂-EDA), (Penta-MeCp)Nb(=NnPr)(EDA), (Penta-MeCp)Nb(=NnPr)(Me₂-EDA), (Penta-MeCp)Nb(=NnPr)(Et₂-EDA), (Penta-MeCp)Nb(=NnPr)(nPr₂-EDA), (Penta-MeCp)Nb(=NnPr)(iPr₂-EDA), (Penta-MeCp)Nb(=NnPr)(nBu₂-EDA), (Penta-MeCp)Nb(=NnPr)(tBu₂-EDA), (Penta-MeCp)Nb(=NnPr)(nPentyl₂-EDA), or (Penta-MeCp)Nb(=NnPr)(tAm₂-EDA).

More preferably, the disclosed precursor is Niobium tButyl Imide Cyclopentadienyl tAmyl-Diazadienyl, CpNb(=NtBu)(tAm₂-DAD). This precursor may be synthesized by reacting lithium tAmyl-Diazadienyl with Nb(=NtBu)Cl₃(py)₂ and Sodium Cyclopentadienyl in THF.

The disclosed precursors have the flowing advantages. The disclosed precursors have high thermal stability, so that a high deposition temperature and a broad ALD window are expected. In addition, the disclosed precursors are liquid precursors and therefore easier for vaporization and vapor delivery.

Purity of the disclosed Group V-containing film forming composition is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR and gas liquid chromatography with mass spectrometry. The disclosed Group V-containing film forming compositions may contain any of the following impurities: pyrazoles; pyridines; alkylamines; alkylimines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallisation, sublimation, distillation, and/or passing the gas liquid through a suitable adsorbent, such as a 4 Å molecular sieve.

Purification of the disclosed Group V-containing film forming composition may also result in metal impurities at the 0 ppbw to 1 ppmw, preferably 0-500 ppbw (part per billion weight) level. These metal impurities may include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

Also disclosed are methods for forming Group V-containing layers on a substrate using a vapor deposition process. Applicants believe, and demonstrate in the Deposition Example that follows, that the disclosed Group V-containing film forming compositions are suitable for atomic layer deposition (ALD). More particularly, the disclosed Group V-containing film forming compositions are capable of surface saturation, self limited growth per cycle, and perfect step coverage on aspect ratios ranging from approximately 2:1 to approximately 200:1; and preferably from approximately 20:1 to approximately 100:1. Additionally, the disclosed Group V-containing film forming compositions have high decomposition temperatures, indicating good thermal stability to enable ALD. The high decomposition temperatures permit ALD at higher temperatures; resulting in films having higher purity.

The disclosed method may be useful in the manufacture of semiconductor, photovoltaic, LCD-TFT; flat panel type devices. The disclosed Group V-containing film forming compositions may be used to deposit Group V-containing films using any deposition methods known to those of skill in the art. Examples of suitable vapor deposition methods include chemical vapor deposition (CVD) atomic layer deposition (ALD). Exemplary CVD methods include thermal CVD, plasma enhanced CVD (PECVD), pulsed CVD (PCVD), low pressure CVD (LPCVD), sub-atmospheric CVD (SACVD) atmospheric pressure CVD (APCVD), hot-wire CVD (HWCVD, also known as cat-CVD, in which a hot wire serves as an energy source for the deposition process), radicals incorporated CVD, and combinations thereof. Exemplary ALD methods include thermal ALD, plasma enhanced ALD (PEALD), spatial ALD, hot-wire ALD (HWALD), radicals incorporated ALD, and combinations thereof, Super critical fluid deposition may also be used. The deposition method is preferably ALD, PE-ALD, spatial ALD in order to provide suitable step coverage and film thickness control,

The disclosed Group V-containing film forming compositions may be supplied either in neat form in a blend with a suitable solvent, such as ethyl benzene, xylene, mesitylene, decalin, decane, dodecane. The disclosed precursors may be present in varying concentrations in the solvent.

The neat blended Group V-containing film forming compositions are introduced into a reactor in vapor form by conventional means, such as tubing and/or flow meters. The vapor form may be produced by vaporizing the neat blended composition through a conventional vaporization step such as direct vaporization, distillation, by bubbling, or by using a sublimator. The neat blended composition may be fed in liquid state to a vaporizer where it is vaporized before it is introduced into the reactor. Alternatively, the neat blended composition may be vaporized by passing a carrier gas into a container containing the composition by bubbling the carrier gas into the composition. The carrier gas may include, but is not limited to, Ar, He, N₂, and mixtures thereof. Bubbling with a carrier gas may also remove any dissolved oxygen present in the neat blended composition. The carrier gas and composition are then introduced into the reactor as a vapor,

If necessary, the container containing the disclosed Group V-containing film forming composition may be heated to a temperature that permits the composition to be in its liquid phase and to have a sufficient vapor pressure. The container may be maintained at temperatures in the range of, for example, approximately 0° C. to approximately 200° C. Those skilled in the art recognize that the temperature of the container may be adjusted in a known manner to control the amount of precursor vaporized.

The reactor may be any enclosure chamber within a device in which deposition methods take place such as without limitation, a parallel-plate type reactor, a cold-wall type reactor, a hot-wall type reactor, a single-wafer reactor, a multi-wafer reactor, a powder ALD reactor, other types of deposition systems under conditions suitable to cause the compounds to react and form the layers. One of ordinary skill in the art will recognize that any of these reactors may be used for either ALD or CVD deposition processes.

The reactor contains one more substrates onto which the films will be deposited. A substrate is generally defined as the material on which a process is conducted. The substrates may be any suitable substrate used in semiconductor, photovoltaic, fiat panel, LCD-TFT device manufacturing. Examples of suitable substrates include wafers, such as silicon, silica, glass, GaAs wafers. The wafer may have one more layers of differing materials deposited on it from a previous manufacturing step. For example, the wafers may include a dielectric layer. Furthermore, the wafers may include silicon layers (crystalline, amorphous, porous, etc,), silicon oxide layers, silicon nitride layers, silicon oxy nitride layers, carbon doped silicon oxide (SiCOH) layers, metal, metal oxide, metal nitride layers (Ti, Ru, Ta, etc,) combinations thereof. Additionally, the wafers may include copper layers noble metal layers (e.g., platinum, palladium, rhodium, and gold). Plastic layers, such as poly(3,4-ethylenedioxythiophene)poly(styrenesulfonate)[PEDOT:PSS] may also be used. The layers may be planar or patterned. The disclosed processes may deposit the Group V-containing layer directly on the wafer or directly on one or more layers on top of the wafer (when patterned layers form the substrate). Furthermore, one of ordinary skill in the art will recognize that the terms “film” “layer” used herein refer to a thickness of some material laid on spread over a surface and that the surface may be a trench a line. Throughout the specification and claims, the wafer and any associated layers thereon are referred to as substrates. For example, a Niobium oxide film may be deposited onto a metal oxide layer, such as a ZrO₂ layer, an HfO₂ layer, an Al₂O₃ layer, a MoO₂ layer. In subsequent processing, another metal oxide layer may be deposited on the Niobium oxide layer to form a nanolaminate; for example, ZrO₂/Nb₂O₅/ZrO₂ laminate dielectric stack are typical of DRAM high-k stack. A conductive metal nitride layer, such as a Niobium Nitride layer or a Titanium Nitride layer, may be deposited before on the last metal oxide layer to form, respectively, the bottom and top electrodes. The resulting NbN/ZrO_{2/}Nb₂O₅/ZrO₂/NbN stack may be used in DRAM capacitors. Other conductive films, such as RuO, Ru, Pt, Ir, WN, WNC, may be also used as the bottom top electrodes, alone in addition to the NbN or TaN layers.

The substrate may also be a powder, such as the powder used in rechargeable battery technology. A non-limiting number of powder materials include NMC (Lithium Nickel Manganese Cobalt Oxide), LCO (Lithium Cobalt Oxide), LFP (Lithium Iron Phosphate), and other battery cathode materials.

The temperature and the pressure within the reactor are held at conditions suitable for ALD. In other words, after introduction of the vaporized disclosed composition into the chamber, conditions within the chamber are such that at least part of the precursor is deposited onto the substrate to form a Group V (five)-containing layer. For instance, the pressure in the reactor or the deposition pressure may be held between about 10⁻³ torr and about 100 Torr, more preferably between about 10⁻² and 100 Torr, as required per the deposition parameters. Likewise, the temperature in the reactor or the deposition temperature may be held between about 100° C. and about 600° C., preferably between about 150° C. and about 500° C. One of ordinary skill in the art will recognize that “at least part of the precursor is deposited” means that some all of the precursor reacts with adheres to the substrate.

The temperature of the reactor may be controlled by either controlling the temperature of the substrate holder controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 50° C. to approximately 600° C. When a plasma deposition process is utilized, the deposition temperature may range from approximately 50° C. to approximately 500° C., preferably, from approximately 100° C. to approximately 500° C., more preferably, from approximately 150° C. to approximately 500° C. Alternatively, when a thermal process is performed, the deposition temperature may range from approximately 100° C. to approximately 600° C.

In addition to the disclosed Group V-containing film forming composition, a co-reactant may be introduced into the reactor. When the target is a conductive film, the co-reactant may be H₂, H₂CO, N₂H₄, NH₃, a primary amine, a secondary amine, a tertiary amine, trisilylamine, a hydrazine N(SiH₃)₃, Si₂H₆, radicals thereof, and mixtures thereof. Preferably, the co-reactant is H₂/NH₃.

Alternatively, when the target is a dielectric film, the co-reactant may be an oxidizing gas such as one of O₂, O₃, H₂O, H₂O₂, NO, N₂O, NO₂, oxygen containing radicals such as O— OH—, carboxylic acids, formic acid, acetic acid, propionic acid, and mixtures thereof. Preferably, the oxidizing gas is selected from the group consisting of O₃, H₂O₂ H₂O.

The co-reactant may be treated by a plasma, in order to decompose the reactant into its radical form, N₂ may also be utilized as a nitrogen source gas when treated with plasma. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The co-reactant may be introduced and held in the reaction chamber prior to plasma processing. Alternatively, the plasma processing may occur simultaneously with the introduction of the reactant, In-situ plasma is typically a 13.56 MHz RF inductively coupled plasma that is generated between the showerhead and the substrate holder. The substrate the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the co-reactant using in-situ plasma is typically less than achieved using a remote plasma source for the same power input and is therefore not as efficient in reactant dissociation as a remote plasma system, which may be beneficial for the deposition of Group V (five)-containing films on substrates easily damaged by plasma.

Alternatively, the plasma-treated co-reactant may be produced outside of the reaction chamber, for example, a remote plasma to treat the co-reactant prior to passage into the reaction chamber.

The ALD conditions within the chamber allow the disclosed Group V-containing film forming composition adsorbed chemisorbed on the substrate surface to react and form a Group V-containing film on the substrate. In some embodiments, Applicants believe that plasma-treating the co-reactant may provide the co-reactant with the energy needed to react with the disclosed Group V-containing film forming composition.

Depending on what type of film is desired to be deposited, an additional precursor compound may be introduced into the reactor. The additional precursor may be used to provide additional elements to the Group V-containing film. The additional elements may include Group I elements (lithium, Sodium, potassium), lanthanides (Ytterbium, Erbium, Dysprosium, Gadolinium, Praseodymium, Cerium, Lanthanum, Yttrium), Group IV elements (zirconium, titanium, hafnium), main group elements (germanium, silicon, aluminium), additional different Group V elements, and mixtures thereof. When an additional precursor compound is utilized, the resultant film deposited on the substrate contains the Group V metal in combination with an additional element. When the additional precursor and the Group V precursors are used in more than one ALD super cycle sequences, a nanolaminate film is obtained. For instance, when an additional Li-containing precursor is used, the Group V-containing film will contain Li, such as, a lithium noibiate (LiNbO₃) film. One of ordinary skilled in the art will recognize the Group V-containing films containing Li may be formed by ALD on any types of substrates including a powder.

The Group V-containing film forming composition and co-reactants may be introduced into the reactor sequentially (i.e., ALD). The reactor may be purged with an inert gas (e.g., N₂, He, Ar, Kr, or Xe) between the introduction of each of the Group V-containing film forming composition, any additional precursors, and the co-reactants. Another example is to introduce the co-reactant continuously and to introduce the Group V-containing film forming composition by pulse, while activating the co-reactant sequentially with a plasma, provided that the Group V-containing film forming composition and the non-activated co-reactant do not substantially react at the chamber temperature and pressure conditions (CW PEALD).

Each pulse of the disclosed Group V-containing film forming composition may last for a time period ranging from about 0.01 seconds to about 120 seconds, alternatively from about 1 seconds to about 80 seconds, alternatively from about 5 seconds to about 30 seconds. The co-reactant may also be pulsed into the reactor, In such embodiments, the pulse of each may last for a time period ranging from about 0.01 seconds to about 120 seconds, alternatively from about 1 seconds to about 30 seconds, alternatively from about 2 seconds to about 20 seconds. In another alternative, the vaporized Group V-containing film forming compositions and co-reactants may be simultaneously sprayed from different sectors of a shower head (without mixing of the composition and the reactant) under which a susceptor holding several wafers is spun (spatial ALD).

Depending on the particular process parameters, deposition may take place for a varying length of time. Generally, deposition may be allowed to continue as long as desired necessary to produce a film with the necessary properties. Typical film thicknesses may vary from several angstroms to several hundreds of microns, and typically from 2 to 100 nm, depending on the specific deposition process. The deposition process may also be performed as many times as necessary to obtain the desired film.

In one non-limiting exemplary ALD process, the vapor phase of the disclosed Group V-containing film forming composition is introduced into the reactor, where it is contacted with a suitable substrate. Excess composition may then be removed from the reactor by purging and/or evacuating the reactor. A co-reactant (for example, O₃) is introduced into the reactor where it reacts with the absorbed Group V-containing film forming composition in a self-limiting manner. Any excess co-reactant is removed from the reactor by purging and/or evacuating the reactor. If the desired film is a Group V-containing oxide, this two-step process may provide the desired film thickness may be repeated until a film having the necessary thickness has been obtained.

Alternatively, if the desired film contains the Group V (five) transition metal and a second element, such as Li, the two-step process above may be followed by introduction of the vapor of an additional precursor compound into the reactor. The additional precursor compound will be selected based on the nature of the Group V-containing film being deposited. After introduction into the reactor, the additional precursor compound is contacted with the substrate. Any excess precursor compound is removed from the reactor by purging and/or evacuating the reactor. Once again, a co-reactant may be introduced into the reactor to react with the precursor compound. Excess co-reactant is removed from the reactor by purging and/or evacuating the reactor. If a desired film thickness has been achieved, the process may be terminated. However, if a thicker film is desired, the entire four-step process may be repeated. By alternating the provision of the Group V-containing film forming composition, additional precursor compound, and co-reactant, a film of desired composition and thickness can be deposited. In one non-limiting exemplary ALD process, the vapor phase of one of the disclosed Group V-containing film forming composition, for example, Niobium tButyl Imido Cyclopentadienyl tAmyl-Diazadienyl, CpNb(=NtBu)(tAm₂-DAD, is introduced into the reactor, where it is contacted with a powder substrate and absorbed thereon. Excess composition may then be removed from the reactor by purging and/or evacuating the reactor. A co-reactant (for example. O₃) is introduced into the reactor where it reacts with the absorbed CpNb(=NtBu)(tAm₂-DAD in a self-limiting manner to form a Nb oxide film. Any excess O₃ gas is removed from the reactor by purging and/or evacuating the reactor. A Li-containing precursor may then be exposed to the powder substrate and/or the Nb oxide film to form a Li and Nb oxide film LiNbO₃. For example, LiOtBu, may serve as the Li precursor. This non-limiting exemplary ALD process described above using CpNb(=NtBu)(tAm₂-DAD, O₃ and LiOtBu may then be repeated on the powder until a desired thickness of the LiNbO₃ film deposited on the powder. The resulting LiNbO₃ film may be used in rechargeable battery applications. One of ordinary skilled in the art will recognize that the suitable lithium precursors include, but are not limited to, LiOtBu, LiN(SiR₃)₂ wherein each R is selected from H, a C₁ to C₄ alkyl or alkeny group, Li(DPM) (lithium dipivaloylmethane aka lithium 2,2,6,6-tetramethyl-3,5-heptanedionate) or any other suitable lithium ALD precursors.

When the co-reactant in this exemplary ALD process is treated with a plasma, the exemplary ALD process becomes an exemplary PEALD process. The co-reactant may be treated with plasma prior subsequent to introduction into the chamber.

In a second non-limiting exemplary ALD process, the vapor phase of one of the disclosed Group V-containing film forming composition, for example Niobium tButyl Imido Cyclopentadienyl tAmyl-Diazadienyl, CpNb(=NtBu)(tAm₂-DAD), is introduced into the reactor, where it is contacted with a Si substrate. Excess composition may then be removed from the reactor by purging and/or evacuating the reactor. A co-reactant (for example, O₃) is introduced into the reactor where it reacts with the absorbed Group V-containing film forming composition in a self-limiting manner to form a Group V-containing oxide film. Any excess gas is removed from the reactor by purging and/or evacuating the reactor. These two steps may be repeated until the Group V-containing oxide film obtains a desired thickness, typically around 10 angstroms, ZrO₂ may then be deposited on the Group V-containing oxide film, For example, ZrCp(NMe₂)₃ or HfCp(NMe₂)₃ may serve as the Zr or Hf precursor repectively. The second non-limiting exemplary ALD process described above using CpNb(=NtBu)(tAm₂-DAD) and O₃ may then be repeated on the ZrO₂ or HfO₂ layer. The resulting Nb₂O_{5/}ZrO₂/Nb₂O₅, Nb₂O₅/HfO₂/Nb₂O₅ or Nb₂0₅/HZO/Nb₂O₅ stack may be used in DRAM capacitors. Here HZO represents Hafnium Zirconium Oxide.

In another exemplary ALD process, another precursor may be introduced sequentially between one several ALD super-cycles (e.g., O-containing co-reactant/ Group V-containing precursor/O-containing co-reactant) in order to deposit a Group V-containing MO film an Group V (five)-containing O/MO nanolaminate, M being selected from a Group IV element, a different group V (five) element, silicon, germanium, aluminium, or any lanthanide. The M precursor selected preferably undergoes ALD growth in the same temperature window exhibited by the selected Group V-containing film forming composition.

The Group V-containing films resulting from the processes discussed above may include Nb, NbₖSiₗ, NbₙOₘ, NbₒNₚ, NbₒNₚO_{q}, wherein k, l, m, n, o, p, and q may each independently range from 1 to 6. Exemplary films include NbO₂, Nb₂O₅, NbN, and NbON, One of ordinary skill in the art will recognize that by appropriate selection of the Group V-containing film forming composition co-reactants, the desired film composition may be obtained. The Group V-containing films may provide suitable step coverage for capacitor electrodes in DRAM, the gate metal in 3D Flash memory devices, the heating element in phase change memory, the electromigration barrier layer, gate metal, and contact layers in logic devices.

Upon obtaining a desired film thickness, the film may be subject to further processing, such as thermal annealing, furnace-annealing, rapid thermal annealing, UV e-beam curing, and microwave annealing and/or plasma gas exposure. Those skilled in the art recognize the systems and methods utilized to perform these additional processing steps. For example, the Nb₂O₅ film may be exposed to a temperature ranging from approximately 200° C. and approximately 1000° C. for a time ranging from approximately 0.1 second to approximately 7200 seconds under an inert atmosphere, an O-containing atmosphere, H-containing atmosphere combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Nb₂O₅ film. This in turn tends to improve the resistivity of the film.

After annealing, the Group V-containing films deposited by any of the disclosed processes may have a bulk resistivity at room temperature of approximately 50 μohm·cm to approximately 1,000 μohm·cm. Room temperature is approximately 20° C. to approximately 28° C. depending on the season. Bulk resistivity is also known as volume resistivity. One of ordinary skill in the art will recognize that the bulk resistivity is measured at room temperature on the Group V-containing films that are typically approximately 50 nm thick. The bulk resistivity typically increases for thinner films due to changes in the electron transport mechanism. The bulk resistivity also increases at higher temperatures.

In another alternative, the disclosed compositions may be used as doping implantation agents. Part of the disclosed Group V-containing film forming composition may be deposited on top of the film to be doped, such as an indium oxide (In₂O₃) film, tantalum dioxide (TaO₂), vanadium dioxide (VO₂) film, a titanium oxide film, a copper oxide film, or a tin dioxide (SnO₂) film. The Group V (five) element, for example Nb, then diffuses into the film during an annealing step to form the Group V (five) element-doped films, such as {(Nb)In₂O₃, (Nb)VO₂, (Nb)TiO, (Nb)CuO, (Nb)SnO₂}. See, e.g., US2008/0241575 to Lavoie et al., the doping method of which is incorporated herein by reference in its entirety.

### EXAMPLES

The following non-limiting examples are provided to further illustrate embodiments of the invention. However, the examples are not intended to be all inclusive and are not intended to limit the scope of the inventions described herein.

### Example 1. Synthesis of Niobium tButyl Imido Cyclopentadienyl tAmyl-Diazadienyl, CpNb(=NtBu)(tAm₂-DAD)

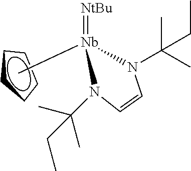

A solution of Sodium Cyclopentadienyl (2.4 mL. 2.0 M, 4.8 mmol) was added dropwise to a solution of Nb(=NtBu)Cl₃(py)₂ (2 g, 4.6 mmol) in 30 mL of THF at −78° C. to form a mixture. The mixture was stirred under room temperature for 12 h. The color of the mixture turned to yellow, A fresh red solution of lithium tAmyl-Diazadienyl in THF, prepared from the reaction of tAmyl-Diazadiene (0.9 g, 4.6 mmol) and pure Lithium (80 mg, 11.5 mmol), was then added to the mixture at −78° C. Afterwards the color of the mixture turned to dark brown. After stirring overnight under room temperature, the solvent was removed from the mixture under vacuum and a brown oil product was extracted with pentane, The brown oil product was then purified by distillation up to 220° C. @ 25 mTorr to give 0.23 g (11%) of brown oil. The purified product was characterized by NMR ¹H (δ, ppm, C₆D₆): 5.68 (s, 5H), 5.65 (s, 2H), 1.60 (m, 4H), 1.29 (s, 6H), 1.26(s, 9H), 1.14 (s, 6H), 0.79(t, 6H).

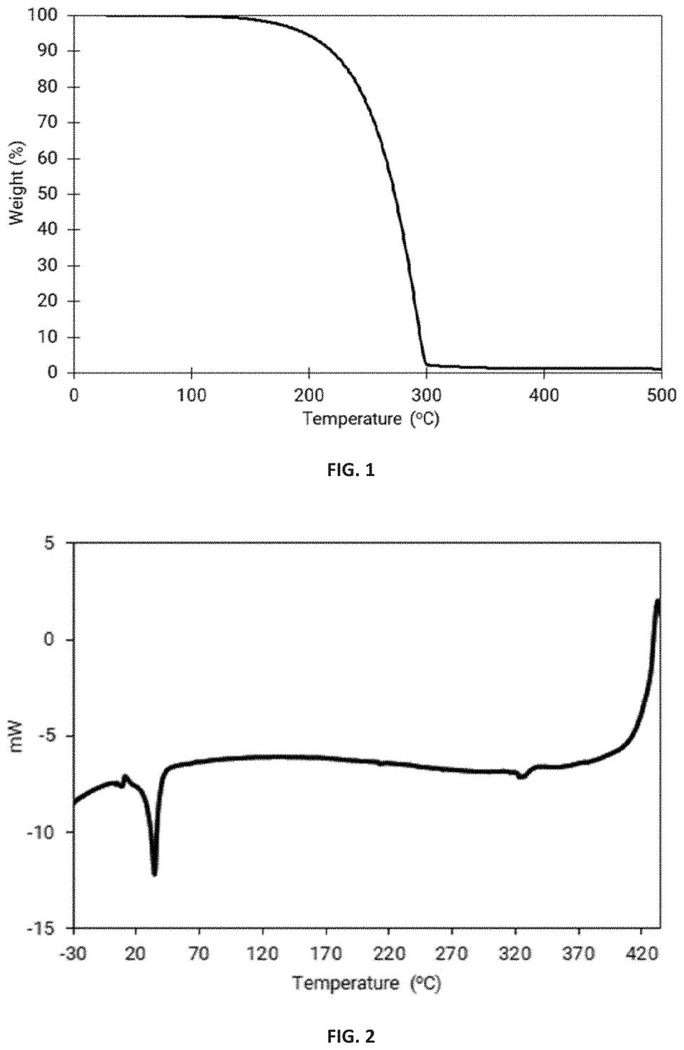

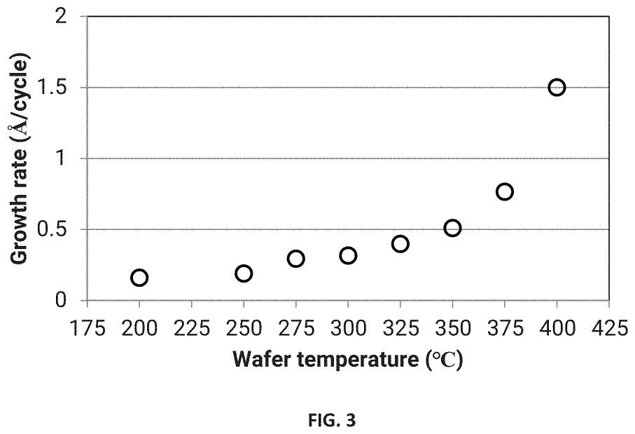

The purified product left a 1.2% residual mass during open-cup TGA analysis measured at a temperature rising rate of 10° C./min in an inert atmosphere that flows nitrogen at 200 mL/min. The results are shown in FIG. 1, which is a TGA graph illustrating the percentage of weight loss upon temperature increase. Onset temperature of melting (26° C.) and decomposition (422° C.) of the product were measured by differential scanning calorimetry (DSC), which are shown in FIG. 2.

### Example 2. ALD Results of Niobium tButyl Imido Cyclopentadienyl tAmyl-Diazadienyl, CpNb(=NtBu)(tAm₂-DAD)

CpNb(=NtBu)(tAm₂-DAD) was stored in a container. The container was heated at 90° C., and Ar was used as a carrier gas to carry CpNb(=NtBu)(tAm₂-DAD) into a reactor at a flow of 200 sccm. O₃ was used as oxygen source. The substrate was heated from 200 to 400° C. During a first step, CpNb(=NtBu)(tAm₂-DAD) (with the carrier gas Ar) was introduced into the reaction chamber in 10 s. An Ar purge of 10 s was performed afterwards as second step. As third step, a pulse of O₃ was then introduced into the reaction chamber in 1 s, followed by a 10 s Ar purge as fourth step. All four steps were repeated 200 times to obtain an Nb₂O₅ film. Self-limited atomic layer deposition was obtained.

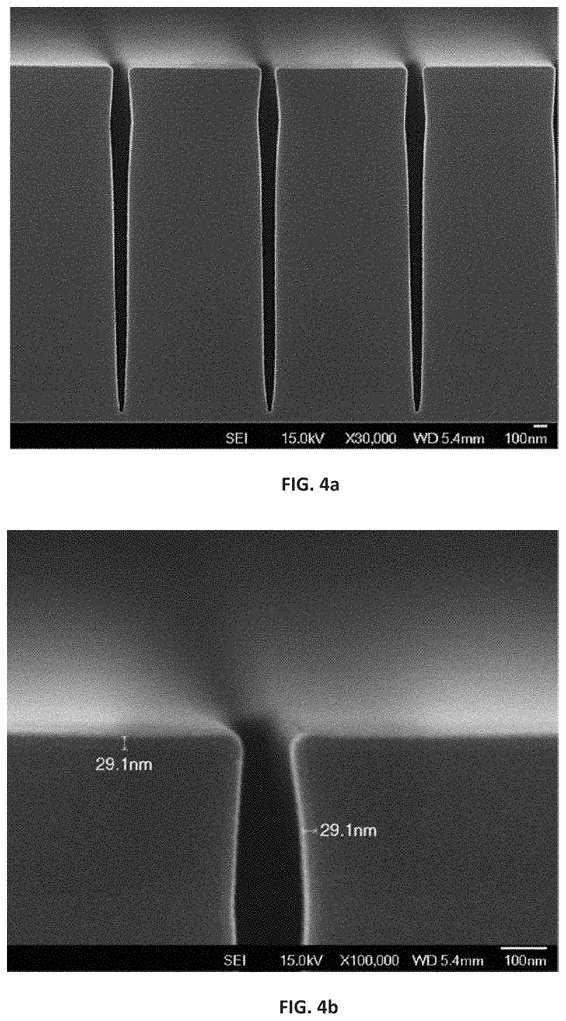

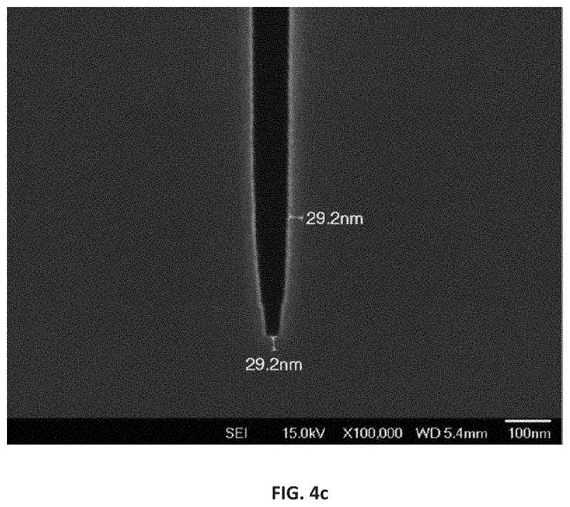

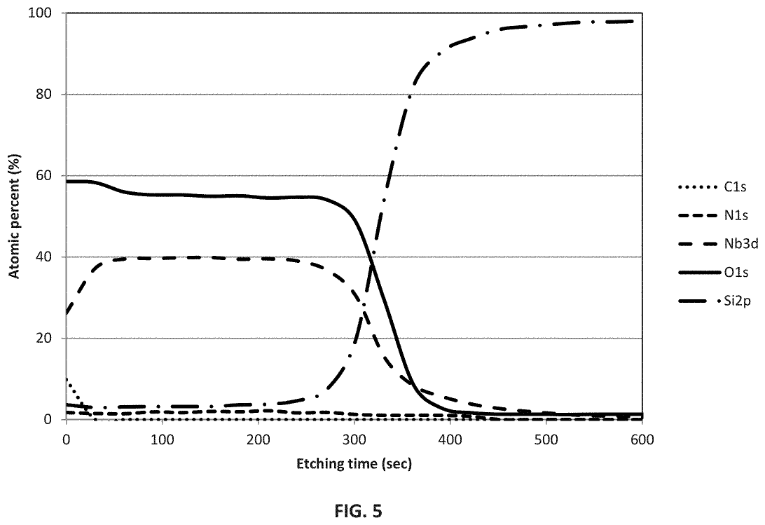

FIG. 3, FIGS. 4a to 4c and FIG. 5 are the ALD results of OpNb(=NtBu)(tAm₂-DAD), The growth rate was 0.3 Å per cycle and the ALD window was up to 325° C. (FIG. 3). FIG. 4a showed a full image of excellent step coverage in 1:15 aspect ratio patterned wafer at 325° C. by SEM. FIG. 4b showed top image of FIG. 4a and FIG. 4c showed bottom image of FIG. 4a. FIG. 5 is an XPS depth profile that shows proper composition ratio of Nb₂O₅ and negligible impurity level at 325° C.

Although the subject matter described herein may be described in the context of illustrative implementations to process one or more computing application features/operations for a computing application having user-interactive components the subject matter is not limited to these particular embodiments. Rather, the techniques described herein may be applied to any suitable type of user-interactive component execution management methods, systems, platforms, and/or apparatus.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

1. A method for forming a Group V (five)-containing film, the method comprising the steps of:
a) exposing a substrate to a vapor of a Group V (five)-containing film forming composition;
b) exposing the substrate to a co-reactant; and
c) repeating the steps of a) and b) until a desired thickness of the Group V (five)-containing film is deposited on the substrate using a vapor deposition process,
wherein the Group V (five)-containing film forming composition comprises a precursor having the formula: 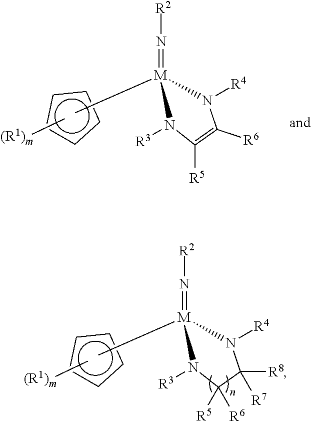
wherein M is Group V (five) element, vanadium (V), niobium (Nb), or tantalum (Ta);
R¹ to R⁸ each is H, a C₁-C₆ alkyl group, a fluoro group, an alkylsilyl group, a germyl group, an alkylamide or an alkylsilylamide; m=1 to 5, n=1 to 5.

2. The method of claim 1, further comprising the step of
introducing an inert gas purge following the steps a) and b), respectively, to separate each exposure, wherein the inert gas purge uses an inert gas selected from N₂, He, Ar, Kr, or Xe.

3. The method of claim 1, further comprising the step of plasma treating the co-reactant.

4. The method of claim 1, wherein the co-reactant is selected from the group consisting of O₂, O₃, H₂O, H₂O₂, NO, N₂O, NO₂, oxygen radicals thereof, and mixtures thereof.

5. The method of claim 1, wherein the co-reactant is selected from the group consisting of H₂, H₂CO, N₂H₄, NH₃, an amine, a hydrazine N(SiH₃)₃, B₂H₆, Si₂H₆ radicals thereof, and mixtures thereof.

6. The method of claim 1, wherein the co-reactant is NH₃ or O₃.

7. The method of claim 1, wherein the precursor includes (R³R⁴R⁵R⁶R⁷Cp)Nb(=NR¹)(R²₂-DAD), 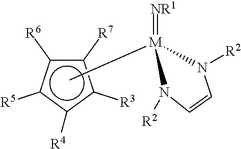
and (R³R⁴R⁵R⁶R⁷Cp)Nb(=NR¹)(R²₂-EDA), 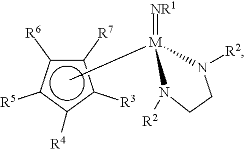
wherein DAD=Diazadiene; EDA is Ethylenediamine; R¹ is tBu or nPr ; R² is Me, Et, nPr, iPr, nBu, tBu, nPentyl or tAm; R³, R⁴, R⁵, R⁶ and R⁷ each is Independently H, Me, Et, nPr, iPr, nBu, tBu or sBu.

8. The method of claim 1, wherein the precursor is Niobium tButyl Imido Cyclopentadienyl tAmyl-Diazadienyl, CpNb(=NtBu)(tAm₂-DAD).

9. The method of claim 1, wherein the Group V (five)-containing film is an Nb₂O₅ film or an NbN film.

10. The method of claim 1, wherein the vapor deposition process is an ALD process or a CVD process.

11. The method of claim 1, wherein a deposition temperature ranges from approximately 50° C. and approximately 600° C.

12. A Group V (five)-containing film forming composition for a vapor deposition process comprising a precursor having the formula: 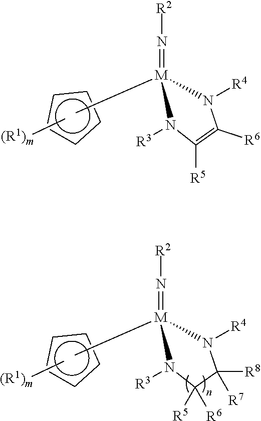
wherein M is Group V (five) element, vanadium (V), niobium (Nb), or tantalum (Ta);
R¹ to R⁸ each is H, a C₁-C₆ alkyl group, a fluoro group, an alkylsilyl group, a germyl group, an alkylamide or an alkylsilylamide; m=1 to 5, n=1 to 5.

13. The Group V (five)-containing film forming composition of claim 12, wherein R¹ to R⁸ each is independently H, Me, Et, nPr, iPr, tBu, sBu, iBu, nBu, tAmyl, SiMe₃, SiMe₂H, or SiH₂Me.

14. The Group V (five)-containing film forming composition of claim 12, wherein the precursor includes (R³R⁴R⁵R⁶R⁷Cp)Nb(=NR¹)(R²₂-DAD), 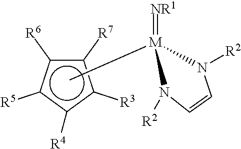
and (R³R⁴R⁵R⁶R⁷Cp)Nb(=NR¹)(R²₂-EDA), 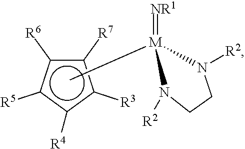
wherein DAD=Diazadiene; EDA is Ethylenediamine; R¹ is tBu or nPr ; R² is Me, Et, nPr, iPr, nBu, tBu, nPentyl or tAm; R³, R⁴, R⁵, R⁶ and R⁷ each is Independently H, Me, Et, nPr, iPr, nBu, tBu or sBu.

15. The Group V (five)-containing film forming composition of claim 12, wherein the precursor is Niobium tButyl Imido Cyclopentadienyl tAmyl-Diazadienyl, CpNb(=NtBu)(tAm₂-DAD).

16. The Group V (five)-containing film forming composition of claim 12, wherein the Group V (five)-containing film forming composition comprises between approximately 95% w/w and approximately 100.0% w/w of the precursor.

17. A method of forming an Nb₂O₅ film or coating by an ALD process on a substrate, the method comprising the steps of:
a) exposing the substrate to a vapor of Niobium tButyl Imido Cyclopentadienyl tAmyl-Diazadienyl (CpNb(=NtBu)(tAm₂-DAD));
b) exposing the substrate to an oxidizer; and
c) repeating the steps of a) and b) until a desired thickness of the Nb₂O₅ film is deposited on the substrate using the ALD process.

18. The method of claim 17, further comprising the steps of
introducing an inert gas purge following the steps a) and b), respectively, to separate each exposure.

19. The method of claim 17, wherein the substrate is a powder.

20. The method of claim 19, wherein the powder comprises one or more of NMC (Lithium Nickel Manganese Cobalt Oxide), LCO (Lithium Cobalt Oxide), LFP (Lithium Iron Phosphate), and other battery cathode materials.
